(19) United States
(12) Patent Application Publication
(10) Pub. No.: US 2015/0084104 A1
(43) Pub. Date: Mar. 26, 2015

(54) METHOD OF MANUFACTURING A SEMICONDUCTOR DEVICE AND THE SEMICONDUCTOR DEVICE

(71) Applicant: Renesas Electronics Corporation, Kawasaki-shi (JP)

(72) Inventor: Yuji ANDO, Kanagawa (JP)

(73) Assignee: Renesas Electronics Corporation, Kawasaki-shi (JP)

(21) Appl. No.: 14/474,999

(22) Filed: Sep. 2, 2014

(30) Foreign Application Priority Data
Sep. 24, 2013 (JP) 2013-197426

(51) Int. Cl. H01L 29/20; H01L 21/28; H01L 29/40; H01L 21/02; H01L 29/772; H01L 29/66

(52) U.S. Cl. CPC H01L 29/2003; H01L 29/772; H01L 29/66409; H01L 29/40; H01L 21/0254; H01L 21/28264
USPC 257/288; 438/478

(57) ABSTRACT

Characteristics of a high electron mobility transistor are improved. A stack having an n-type contact layer (n-type AlGaN layer), an electron supply layer (undoped AlGaN layer), and a channel layer (undoped GaN layer) is formed in a growth mode over a Ga plane parallel with a [0001] crystal axis direction. Then, after turning the stack upside down so that the n-type contact layer (n-type AlGaN layer) is situated to the upper surface and forming a trench, a gate electrode is formed by way of a gate insulation film. By stacking the channel layer (undoped GaN layer) and the electron supply layer (undoped AlGaN layer) successively in a [000-1] direction, (1) normally off operation and (2) increase of withstanding voltage can easily be compatible with each other.

### CROSS-REFERENCE TO RELATED APPLICATIONS

The disclosure of Japanese Patent Application No. 2013-197426 on Sep. 24, 2013 including the specification, drawings, and abstract is incorporated herein by reference in its entirety.

### BACKGROUND

The present invention relates to a method of manufacturing a semiconductor device and the semiconductor device, which can be utilized suitably to semiconductor devices, for example, by using nitride semiconductors.

Since GaN type nitride semiconductors have larger band gaps and higher electron speed than those of Si and GaAs, their application use to high withstanding voltage, high power, and high frequency transistors has been expected and development has been progressed vigorously in recent years.

For example, Japanese Unexamined Patent Publication No. 2012-178495 discloses a semiconductor device in which a buffer layer, a channel layer, and an electron supply layer are stacked in a growth mode parallel with [0001] or [000-1] crystal axis. Further, Japanese Unexamined Patent Publication No. 2009-283690 discloses a MOS field effect transistor and Japanese Unexamined Patent Publication No. 2008-270310 discloses vertical transistors by using nitride type semiconductors.

Further, a lateral transistors by using a nitride semiconductor is disclosed by Y. Yamashita, et al., in “Effect of bottom SiN thickness for AlGaN/GaN metal-insulator-semiconductor high electron mobility transistors by using SiN/SiO₂/SiN triple-layer insulators”, Jpn. J. Appl. Phys., vol. 45, pp. L666-L668, 2006. Further, a vertical transistor by using nitride type semiconductors is disclosed by I. Ben-Yaacov. et al., in “AlGaN/GaN current aperture vertical electron transistors”, Conference Digest of Device Res. Conf., pp. 31-32, 2002

### SUMMARY

The present inventors have been engaged in research and development of semiconductor devices by using nitride semiconductors and have now been under earnest study for the improvement of characteristics of semiconductor devices. In the course of the study, it has been found that there is a room for further improvement in the characteristics of the semiconductor devices by using the nitride semiconductors.

Other subjects and novel features of the invention will become apparent by reading the description of the present specification in conjunction with appended drawings.

An outline of typical embodiments disclosed in the present application is to be described simply.

In a method of manufacturing a semiconductor device shown in a preferred embodiment disclosed in the present application, stack in which a second nitride semiconductor layer is epitaxially grown in a direction is formed over a first nitride semiconductor layer, the stack is disposed such that a [000-1] direction of the stack becomes upward, and a gate electrode is formed on the side of the first nitride semiconductor layer.

A semiconductor device shown in a preferred embodiment disclosed in the present application has a gate electrode formed over the first nitride semiconductor layer and disposed above the second nitride semiconductor layer having a band gap larger than that of the first nitride semiconductor layer in which the direction of crystal axis from the first nitride semiconductor layer to the second nitride semiconductor layer is in the [000-1] direction.

According to the method of manufacturing a semiconductor device shown in the following typical embodiment disclosed in the present invention, a semiconductor device of preferred characteristics can be manufactured.

According to the semiconductor devices shown in the following typical embodiments disclosed in the present invention, characteristics of the semiconductor device can be improved.

### BRIEF DESCRIPTION OF THE DRAWINGS

FIG. 1 is a cross sectional view illustrating a configuration of a semiconductor device of a first embodiment;

FIG. 2 is a view illustrating a crystal structure of GaN;

FIG. 3 is a view illustrating a relation between the plane and the orientation in the crystal;

FIG. 4 is a cross sectional view illustrating a step of manufacturing the semiconductor device of the first embodiment;

FIG. 5 is a cross sectional view illustrating a step of manufacturing the semiconductor device of the first embodiment, which is a cross sectional view illustrating a manufacturing step succeeding to FIG. 4;

FIG. 6 is a cross sectional view illustrating a step of manufacturing the semiconductor device of the first embodiment, which is a cross sectional view illustrating a manufacturing step succeeding to FIG. 5;

FIG. 7 is a cross sectional view illustrating a step of manufacturing the semiconductor device of the first embodiment, which is a cross sectional view illustrating a manufacturing step succeeding to FIG. 6;

FIG. 8 is a cross sectional view illustrating a step of manufacturing the semiconductor device of the first embodiment, which is a cross sectional view illustrating a manufacturing step succeeding to FIG. 7;

FIG. 9 is a cross sectional view illustrating a step of manufacturing the semiconductor device of the first embodiment, which is a cross sectional view illustrating a manufacturing step succeeding to FIG. 8;

FIG. 10 is a cross sectional view illustrating a step of manufacturing the semiconductor device of the first embodiment, which is a cross sectional view illustrating a manufacturing step succeeding to FIG. 9;

FIG. 11 is a cross sectional view illustrating a step of manufacturing the semiconductor device of the first embodiment, which is a cross sectional view illustrating a manufacturing step succeeding to FIG. 10;

FIG. 12 is a cross sectional view illustrating a step of manufacturing the semiconductor device of the first embodiment, which is a cross sectional view illustrating a manufacturing step succeeding to FIG. 11;

FIG. 13 is a cross sectional view illustrating a step of manufacturing the semiconductor device of the first embodiment, which is a cross sectional view illustrating a manufacturing step succeeding to FIG. 12;

FIG. 14 is a cross sectional view illustrating a step of manufacturing the semiconductor device of the first embodiment, which is a cross sectional view illustrating a manufacturing step succeeding to FIG. 13;

FIG. 15 is a cross sectional view illustrating a configuration of a semiconductor device of a first comparative example to the first embodiment;

FIG. 16 is a cross sectional view illustrating a configuration of a semiconductor device of a second comparative example to the first embodiment;

FIG. 17A is a view illustrating a profile of a conduction energy just below a gate electrode of the semiconductor device of Comparative Example 1 (portion A-A′) at a gate voltage (0 V);

FIG. 17B is a view illustrating a profile of a conduction energy just below a gate electrode of the semiconductor device of Comparative Example 1 (portion A-A′) at a gate voltage (threshold Vt);

FIG. 18A is a view illustrating a profile of a conduction band energy of the semiconductor device of the first embodiment (FIG. 1) at a gate voltage (0 V);

FIG. 18B is a view illustrating a profile of a conduction band energy of the semiconductor device of the first embodiment (FIG. 1) at a gate voltage (threshold Vt);

FIG. 19 is a cross sectional view illustrating a configuration of a semiconductor device of a second embodiment;

FIG. 20 is a cross sectional view illustrating a step of manufacturing a semiconductor device of a second embodiment;

FIG. 21 is a cross sectional view illustrating a step of manufacturing the semiconductor device of the second embodiment, which is a cross sectional view illustrating a manufacturing step succeeding to FIG. 20;

FIG. 22 is a cross sectional view illustrating a step of manufacturing the semiconductor device of the second embodiment, which is a cross sectional view illustrating a manufacturing step succeeding to FIG. 21;

FIG. 23 is a cross sectional view illustrating a step of manufacturing the semiconductor device of the second embodiment which is a cross sectional view illustrating a manufacturing step succeeding to FIG. 22;

FIG. 24 is a cross sectional view illustrating a step of manufacturing the semiconductor device of the second embodiment, which is a cross sectional view illustrating a manufacturing step succeeding to FIG. 23;

FIG. 25 is a cross sectional view illustrating a step of manufacturing the semiconductor device of the second embodiment which is a cross sectional view illustrating a manufacturing step succeeding to FIG. 24;

FIG. 26 is a cross sectional view illustrating a configuration of a semiconductor device of a third embodiment;

FIG. 27 is a cross sectional view illustrating a step of manufacturing the semiconductor device of the third embodiment;

FIG. 28 is a cross sectional view illustrating a step of manufacturing the semiconductor device of the third embodiment, which is a cross sectional view illustrating a manufacturing step succeeding to FIG. 27;

FIG. 29 is a cross sectional view illustrating a step of manufacturing the semiconductor device of the third embodiment, which is a cross sectional view illustrating a manufacturing step succeeding to FIG. 28;

FIG. 30 is a cross sectional view illustrating a step of manufacturing the semiconductor device of the third embodiment, which is a cross sectional view illustrating a manufacturing step succeeding to FIG. 29;

FIG. 31 is a cross sectional view illustrating a step of manufacturing the semiconductor device of the third embodiment, which is a cross sectional view illustrating a manufacturing step succeeding to FIG. 30;

FIG. 32 is a cross sectional view illustrating a step of manufacturing the semiconductor device of the third embodiment, which is a cross sectional view illustrating a manufacturing step succeeding to FIG. 31;

FIG. 33 is a cross sectional view illustrating a configuration of a semiconductor device of a fourth embodiment;

FIG. 34 is a cross sectional view illustrating a step of manufacturing the semiconductor device of the fourth embodiment;

FIG. 35 is a cross sectional view illustrating a step of manufacturing the semiconductor device of the fourth embodiment, which is a cross sectional view illustrating a manufacturing step succeeding to FIG. 34;

FIG. 36 is a cross sectional view illustrating a step of manufacturing the semiconductor device of the fourth embodiment, which is a cross sectional view illustrating a manufacturing step succeeding to FIG. 35;

FIG. 37 is a cross sectional view illustrating a step of manufacturing the semiconductor device of the fourth embodiment, which is a cross sectional view illustrating a manufacturing step succeeding to FIG. 36;

FIG. 38 is a cross sectional view illustrating a step of manufacturing the semiconductor device of the fourth embodiment, which is a cross sectional view illustrating a manufacturing step succeeding to FIG. 37;

FIG. 39 is a cross sectional view illustrating a step of manufacturing the semiconductor device of the fourth embodiment, which is a cross sectional view illustrating a manufacturing step succeeding to FIG. 38;

FIG. 40 is a cross sectional view illustrating a step of manufacturing the semiconductor device of the fourth embodiment, which is a cross sectional view illustrating a manufacturing step succeeding to FIG. 39;

FIG. 41 is a cross sectional view illustrating a step of manufacturing a semiconductor device of a fifth embodiment;

FIG. 42 is a cross sectional view illustrating a step of manufacturing the semiconductor device of the fifth embodiment, which is a cross sectional view illustrating a manufacturing step succeeding to FIG. 41;

FIG. 43 is a cross sectional view illustrating a step of manufacturing the semiconductor device of the fifth embodiment, which is a cross sectional view illustrating a manufacturing step succeeding to FIG. 42;

FIG. 44 is a cross sectional view illustrating a step of manufacturing the semiconductor device of the fifth embodiment, which is a cross sectional view illustrating a manufacturing step succeeding to FIG. 43;

FIG. 45 is a cross sectional view illustrating a step of manufacturing the semiconductor device of the fifth embodiment, which is a cross sectional view illustrating a manufacturing step succeeding to FIG. 44;

FIG. 46 is a cross sectional view illustrating a step of manufacturing a semiconductor device of a sixth embodiment;

FIG. 47 is a cross sectional view illustrating a step of manufacturing the semiconductor device of the sixth embodiment, which is a cross sectional view illustrating a manufacturing step succeeding to FIG. 46;

FIG. 48 is a cross sectional view illustrating a step of manufacturing the semiconductor device of the sixth embodiment, which is a cross sectional view illustrating a manufacturing step succeeding to FIG. 47;

FIG. 49 is a cross sectional view illustrating a step of manufacturing the semiconductor device of the sixth embodiment, which is a cross sectional view illustrating a manufacturing step succeeding to FIG. 48;

FIG. 50 is a cross sectional view illustrating a step of manufacturing the semiconductor device of the sixth embodiment, which is a cross sectional view illustrating a manufacturing step succeeding to FIG. 49;

FIG. 51 is a cross sectional view illustrating a configuration example of a lateral semiconductor device in which an n-type impurity layer is disposed to a portion of a channel layer; and

FIG. 52 is a cross sectional view illustrating other configuration example of a vertical semiconductor device in which an n-type impurity layer is disposed to a portion of a channel layer.

### DETAILED DESCRIPTION OF THE PREFERRED EMBODIMENTS

In the following embodiments, the embodiments may be described in a plurality of divided sections or embodiments if required for the sake of convenience. However, unless otherwise specified, they are not independent of each other, but are in such a relation that one is a modification, an application example, detailed explanation, supplementary explanation, or the like of a part or the entirety of the other. Further, in the following embodiments, when reference is made to the number of elements or the like (including number of piece, numerical value, quantity, range, or the like), the number of elements is not limited to the specified number, but may be greater than or less than the specified number unless otherwise specified and except the case where the number is apparently limited to the specified number in principle.

Further, in the following embodiments, the constitutional elements thereof (including element steps or the like) are not always essential unless otherwise specified and except the case where they are apparently considered essential in principle. Similarly, in the following embodiments, when reference is made to shapes, positional relationships, or the like of the constitutional elements or the like, they include ones substantially analogous or similar to the shapes or the like unless otherwise specified and except the case where it is considered that they are apparently not so in principle. This is also applicable to the foregoing number or the like (including number of piece, numerical value, quantity, range, or the like).

Embodiments of the present invention are to be described below in details by reference to the drawings. Throughout the drawings for describing the embodiments, members having the same function are given with same or corresponding reference signs, and duplicate description therefor is omitted. Further, when a plurality of similar members (portions) are present, individual or specified portions are sometimes shown by adding symbols to collective signs. Further, in the following embodiments, a description for same or similar portions will not be repeated in principle unless it is particularly required.

Further, in the drawings used for embodiments, hatching may sometimes be omitted even in a cross-sectional view for easy understanding of the drawings.

Further, in cross sectional views, the size for each of portions does not correspond to that of an actual device but a specified portion is sometimes depicted relatively larger for easy understanding of the drawings.

### First Embodiment

A semiconductor device of a preferred embodiment is to be described below specifically with reference to the drawings.

### Explanation for Structure

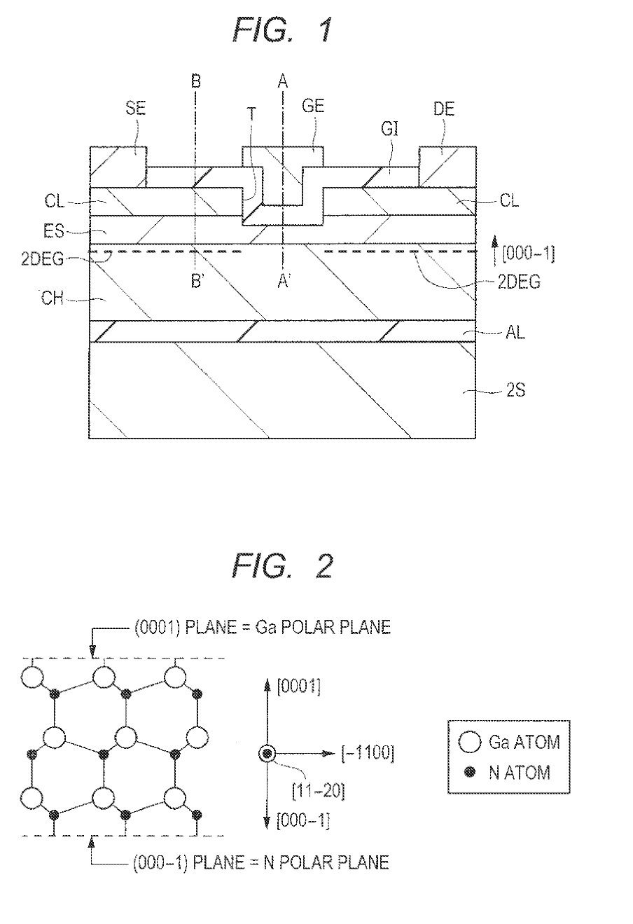

FIG. 1 is a cross sectional view illustrating a configuration of a semiconductor device of a preferred embodiment. The semiconductor device illustrated in FIG. 1 is a field effect transistor (FET) by using nitride semiconductors. This is also referred to as a high electron mobility transistor (HEMT).

As illustrated in FIG. 1, in the semiconductor device of this embodiment, a stack comprising a channel layer (also referred to as electron travel layer) CH, an electron supply layer ES, and an n-type contact layer CL is disposed by way of a bonding layer AL over a support substrate 2S. The stack comprises nitride semiconductors. The electron supply layer ES comprises a nitride semiconductor having a band gap larger than that of the channel layer CH.

In this embodiment, an undoped GaN layer is used as the channel layers CH, an undoped AlGaN layer is used as the electron supply layer ES, and an n-type AlGaN layer is used as the contact layer CL. A two-dimensional electron gas 2DEG is generated near the interface between the electron supply layer ES and the channel layer CH on the side of the channel layer CH.

The junction plane between the electron supply layer (undoped AlGaN layer) ES and the channel layer (undoped GaAl layer) CH is a Ga plane ([0001] plane). The direction from the channel layer (undoped GaN layer) CH to the electron supply layer (undoped AlGaN layer) ES is a [000-1] direction. In other words, the direction from the junction plane (surface that generates a two-dimensional electron gas 2DEG) to the electron supply layer (undoped AlGaN layer) ES is in the [000-1] direction.

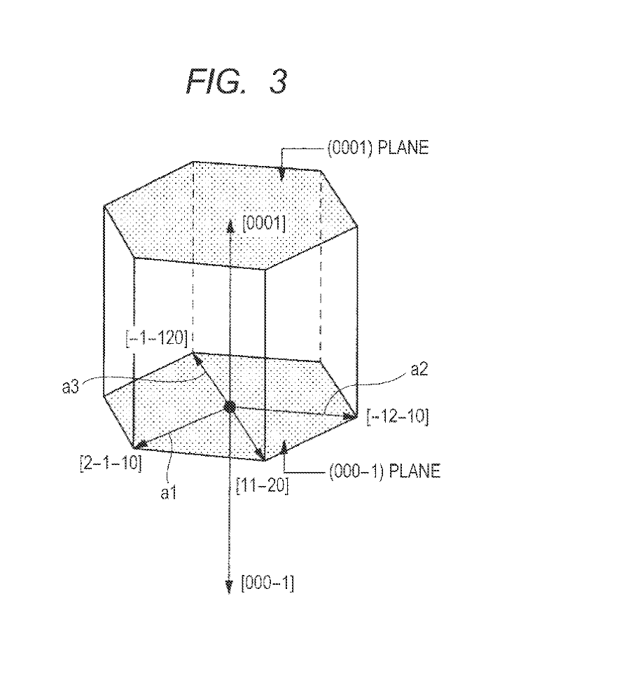

FIG. 2 is a view illustrating a GaN crystal structure and FIG. 3 is a view illustrating a relation between the plane and the orientation of the crystal.

The [000-1] direction (also referred to as [000-1] crystal axis direction) means a direction opposite to a c-axis direction ([0001] direction) as illustrated in FIG. 2 and FIG. 3. Accordingly, the [000-1] direction is a direction of an outward normal vector to the (000-1) plane. In the GaN crystal structure, the (000-1) plane is an N plane (plane on the side of nitrogen, N polar plane).

The [0001] direction (also referred to as [0001] crystal axis direction) means a c-axis direction ([0001] direction) as illustrated in FIG. 2 and FIG. 3. Accordingly, the [0001] direction is a direction of an outward normal vector to the (0001) plane. In the GaN crystal structure, the (0001) plane is a Ga plane (plane on the side of gallium, Ga polar plane).

Further, a gate electrode GE is disposed by way of a gate insulation film GI to the inside of a trench T passing through an n-type contact layer (n-type AlGaN layer) CL and allowing an electron supply layer (undoped AlGaN layer) ES to be exposed from the bottom. A source electrode SE and a drain electrode DE are disposed respectively on both sides of the gate electrode GE over the n-type contact layer (n-type AlGaN layer) CL.

An interlayer insulation film (not illustrated) is disposed over the gate electrode GE. Further, a conductive film filled in contact holes (plugs, not illustrated) formed in the interlayer insulation layer is disposed over the source electrode SE and the drain electrode DE.

### [Explanation for Manufacturing Method]

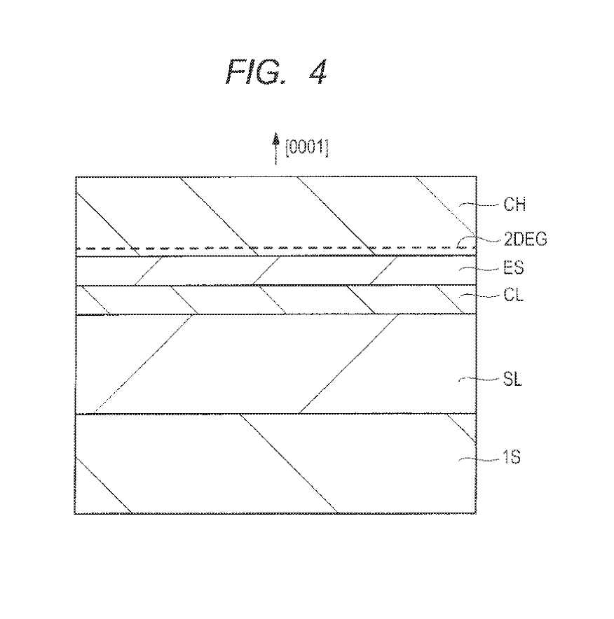

Then, a method of manufacturing the semiconductor device of this embodiment is to be described with reference to FIG. 4 to FIG. 14, and the configuration of the semiconductor device is made clearer. FIG. 4 to FIG. 14 are cross sectional views illustrating manufacturing steps of the semiconductor device of this embodiment.

As illustrated in FIG. 4, a substrate (also referred to as a substrate used for growth) 1S comprising, for example, gallium nitride (GaN) is provided as the substrate.

Then, a sacrificial layer SL is formed by way of a nucleation layer (not illustrated) over the substrate 1S. The sacrificial layer SL comprises, for example, a GaN layer. A sacrificial layer (GaN layer) SL of about 1 μm thickness is deposited over the substrate 1S comprising, for example, gallium nitride (GaN) by using a metal organic chemical vapor deposition method (abbreviated as MOCVD).

Then, an n-type contact layer CL is formed over the sacrificial layer (GaN layer) SL. For example, an n-type AlGaN layer of about 50 nm thickness is deposited by using MOCVD. The AlGaN layer has a compositional ratio represented by Al_{0.2}Ga_{0.8}N. For example, Si (silicon) is used as the n-type impurity and the concentration (impurity concentration) thereof is, for example, about 1×10¹⁹/cm³. Then, an electron supply layer ES is formed over the n-type contact layer (n-type AlGaN layer) CL. For example, an undoped AlGaN layer of about 20 nm thickness is deposited by using MOCVD. The AlGaN layer has a compositional ratio represented by Al_{0.2}Ga_{0.8}N. Then, a channel layer CH is formed over the electron supply layer (undoped AlGaN layer) ES. For example, an undoped GaN layer of about 1 μm thickness is deposited by using MOCVD.

A grown film formed by using MOCVD is referred to as an epitaxial layer (epitaxial film). The stack comprising the sacrificial layer (GaN layer) SL, the n-type contact layer (n-type AlGaN layer) CL, the electron supply layer (undoped AlGaN layer) ES, and the channel layer (undoped GaN layer) CH is formed by a growth mode at the Ga plane parallel with the [0001] crystal axis direction. In other words, respective layers are grown successively over the Ga plane parallel with the [0001] crystal axis direction.

Specifically, GaN is grown in the [0001] direction over the Ga plane ((0001) plane) of the substrate 1S comprising gallium nitride (GaN) to form the sacrificial layer (GaN layer) SL. Then, n-type AlGaN is grown over the Ga plane ((0001) plane) of the sacrificial layer (GaN layer) SL in the [0001] direction to form an n-type contact layer (n-type AlGaN layer) CL. Then, undoped AlGaN is grown over the Ga plane ((0001) plane) of the n-type contact layer (n-type AlGaN layer) CL in the [0001] direction to form an electron supply layer (undoped AlGaN layer) ES. Then, undoped GaN is grown in the direction over the Ga plane ((0001) plane) of the electron supply layer (undoped AlGaN layer) ES to form a channel layer (undoped GaN layer) CH.

A two-dimensional electron gas (two-dimensional electron gas layer) 2DEG is generated (formed) near the interface between the electron supply layer (undoped AlGaN layer) ES and the channel layer (undoped GaN layer) CH. The surface that generates the two-dimensional electron gas 2DEG, that is, the junction plane (interface) between the electron supply layer (undoped AlGaN layer) ES and the channel layer (undoped GaN layer) CH is a Ga plane ((0001) plane) and the direction from the junction plane (plane that generates the two-dimensional gas 2DEG) to the channel layer (undoped GaN layer) CH is the [0001] direction.

As described above, by forming each of the layers of the stack (sacrificial layer (GaN layer) SL, n-type contact layer (n-type AlGaN layer) CL, electron supply layer (undoped AlGaN layer) ES, and channel layer (undoped GaN layer) CH) in a growth mode over the Ga plane parallel with the [0001] crystal axis direction, a stack comprising more planar epitaxial layers with less unevenness can be obtained.

While a lattice constant is different between AlGaN and GaN, a stack of good crystal quality with less occurrence of dislocation can be obtained by setting the total film thickness of AlGaN to a critical film thickness or less.

As the substrate 1S, substrates other than the substrate comprising gallium nitride (GaN) may also be used. By the use of a substrate comprising gallium nitride (GaN), a stack of good crystal quality with less occurrence of dislocation can be grown. Crystal defects such as the dislocation cause leak current. Accordingly, by suppressing the crystal defects, leak current can be decreased and the off voltage withstanding of the transistor can be improved.

As the nucleation layer (not illustrated) over the substrate 1S, a super lattice layer formed by repeatingly stacking stacked films (AlN/GaN films) each comprising a gallium nitride (GaN) layer and an aluminum nitride (AlN) layer can be used.

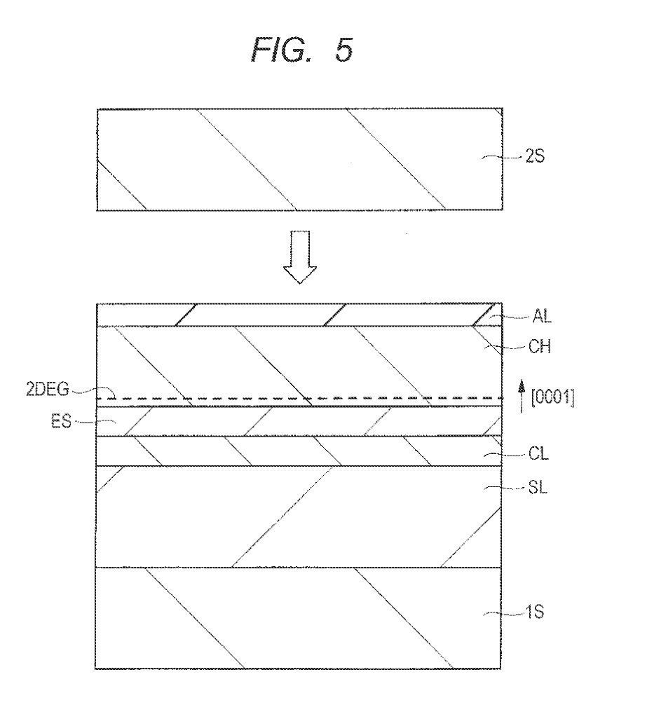

Then, as illustrated in FIG. 5, a bonding layer Al is formed over the (0001) plane of the channel layer (undoped GaN layer) CH and a support substrate 2S is mounted thereover. For example, a coating type insulation film such as hydrogen silsesquioxane (abbreviated as HSQ) can be used as the bonding layer Al. Further, a substrate comprising, for example, silicon (Si) can be used as the support substrate 2S.

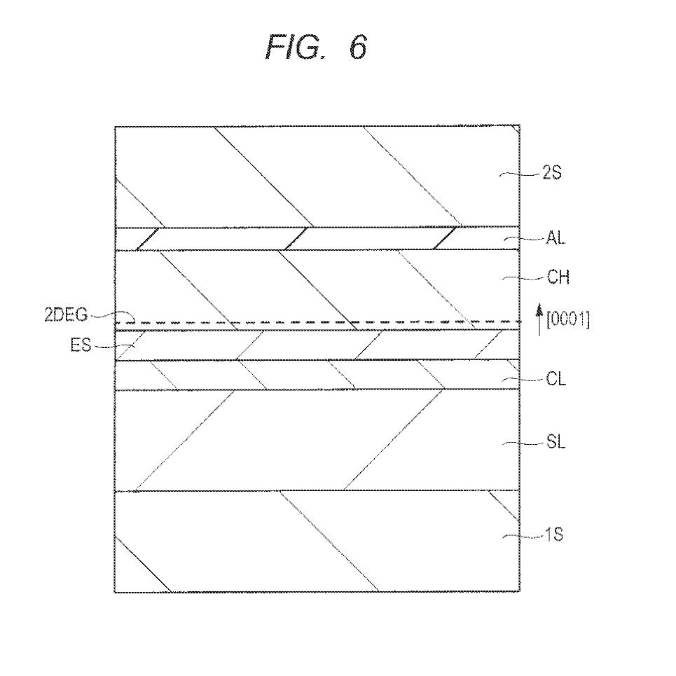

For example, after coating a HSQ precursor on the channel layer (undoped GaN layer) CH and mounting the support substrate 2S, a heat treatment at about 200° C. is applied. Thus, HSQ is hardened and the channel layer (undoped GaN layer) CH and the support substrate 2S can be adhered (bonded) by way of the bonding layer AL as illustrated in FIG. 6. When HSQ is used as the bonding layer AL, it can withstand a thermal load up to about 900° C.

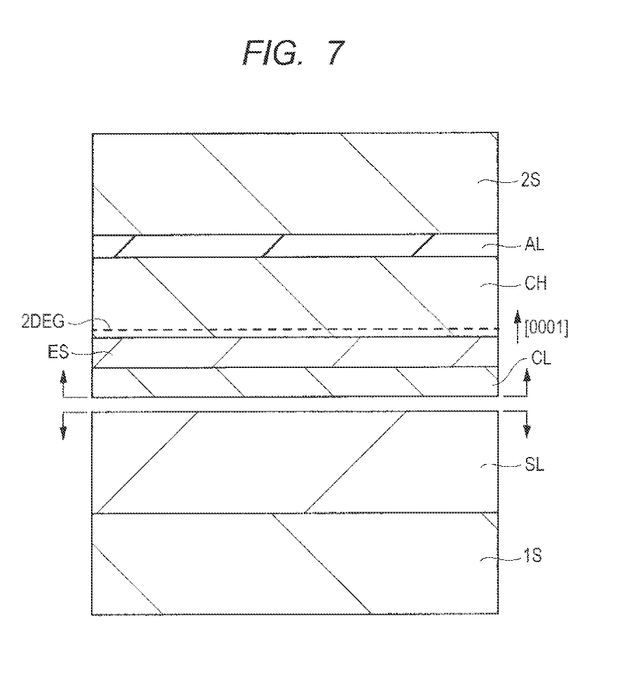

Then, as illustrated in FIG. 7, the sacrificial layer (GaN layer) SL and the substrate 1S are separated from the interface between the sacrificial layer (GaN layer) SL and the n-type contact layer (n-type AlGaN layer) CL. For example, a laser lift off method can be used as the separation method. For example, laser is applied to the interface between the sacrificial layer (GaN layer) SL and the n-type contact layer (n-type AlGaN layer) CL to cause abrasion at the interface between the sacrificial layer (GaN layer) SL and the n-type contact layer (n-type AlGaN layer) CL to form a gap. Then, the sacrificial layer (GaN layer) SL and the substrate 1S are separated from the gap. As a result, a stacked structure in which the electron supply layer (undoped AlGaN layer) ES and the channel layer (undoped GaN layer) CH are stacked over the n-type contact layer (n-type AlGaN layer) CL, and the bonded layer AL and the support substrate 2S are stacked thereover is formed.

Then, as illustrated in FIG. 8, the stacked structure is turned upside down such that the n-type contact layer (n-type AlGaN layer) CL of the stacked structure becomes upward. In other words, the stacked structure is disposed such that the [000-1] direction of the stacked structure becomes upward. Thus, the stack comprising the channel layer (undoped GaN layer) CH, the electron supply layer (undoped AlGaN layer) ES, and the n-type contact layer (n-type AlGaN layer) CL is disposed by way of the bonding layer AL over the support substrate 2S. As described above, the junction plane between the electron supply layer (undoped AlGaN layer) ES and the channel layer (undoped GaN layer) CH is at the Ga plane ((0001) plane). Then, the direction from the junction plane (plane that generates the two-dimensional electron gas 2DEG) to the electron supply layer (undoped AlGaN layer) ES is the [000-1] direction.

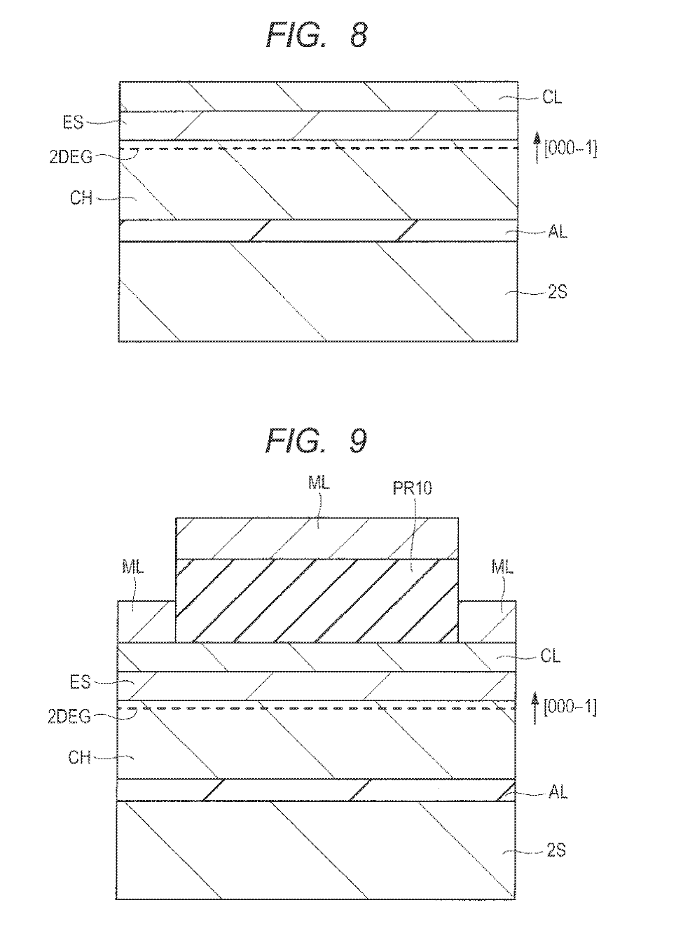

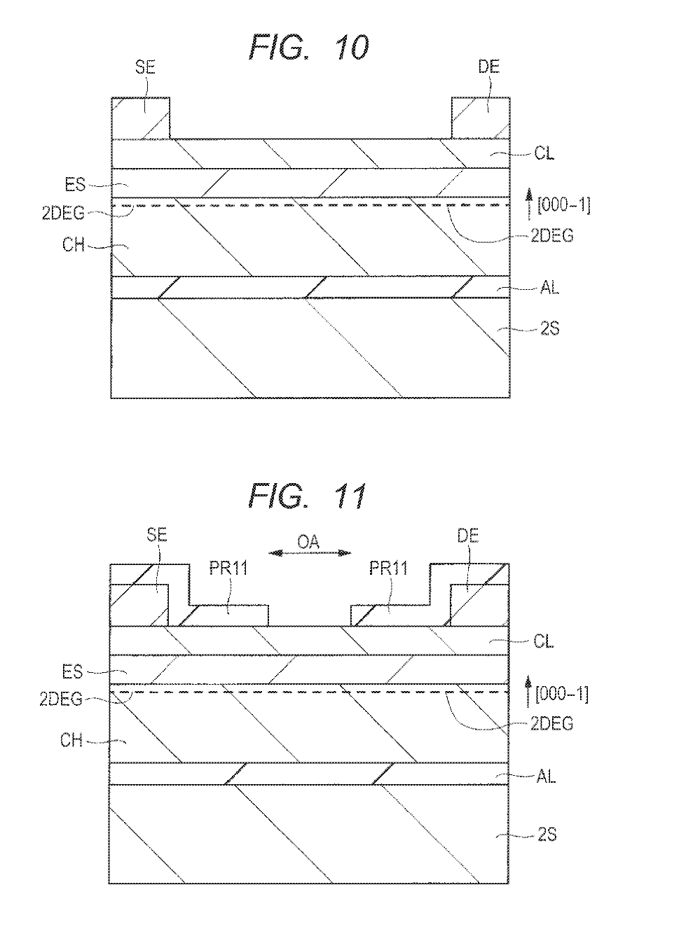

Then, as illustrated in FIG. 9 and FIG. 10, a source electrode SE and a drain electrode DE are formed on both sides of a region over the n-type contact layer (n-type AlGaN layer) CL for forming a gate electrode GE. The source electrode SE and the drain electrode DE can be formed by using, for example, a lift off method. For example, as illustrated in FIG. 9, a photoresist film PR10 is formed over the n-type contact layer (n-type AlGaN layer) CL and exposure and development are applied to remove the photoresist film PR10 over the region for forming the source electrode SE and the drain electrode DE.

Then, a metal film ML is formed over the n-type contact layer (n-type AlGaN layer) CL including a portion over the photoresist film PR10. Thus, the metal film ML is formed directly over the n-type contact layer (n-type AlGaN layer) CL in a region for forming the source electrode SE and the drain electrode DE. On the other hand, the metal film ML is formed over the photoresist film PR10 in other region.

The metal film ML comprises, for example, a stacked film (Ti/Al film) of a titanium (Ti) film and an aluminum (Al) film formed over the titanium film. Each of the films constituting the metal ML can be formed by using, for example, vacuum vapor deposition.

Then, the photoresist film PR10 is removed. In this step, the metal film ML formed over the photoresist film PR10 is also removed together with the photoresist film PR10 to leave only the metal film ML (source electrode SE and the drain electrode DE) formed so as to be in direct contact on the n-type contact layer (n-type AlGaN layer) CL (FIG. 10).

Then, a heat treatment (alloying treatment) is applied to the support substrate 2S. As the heat treatment, a heat treatment, for example, at about 600° C. for one minute in a nitrogen atmosphere is applied. By the heat treatment, the source electrode SE and the channel layer (undoped GaN layer) CH to which the two dimensional electron gas 2DEG can be in ohmic contact. In the same manner, the drain electrode DE and the channel layer (undoped GaN layer) CH can also be in ohmic contact. That is, the source electrode SE and the drain electrode DE are in a state connected electrically to the two-dimensional electron gas 2DEG respectively.

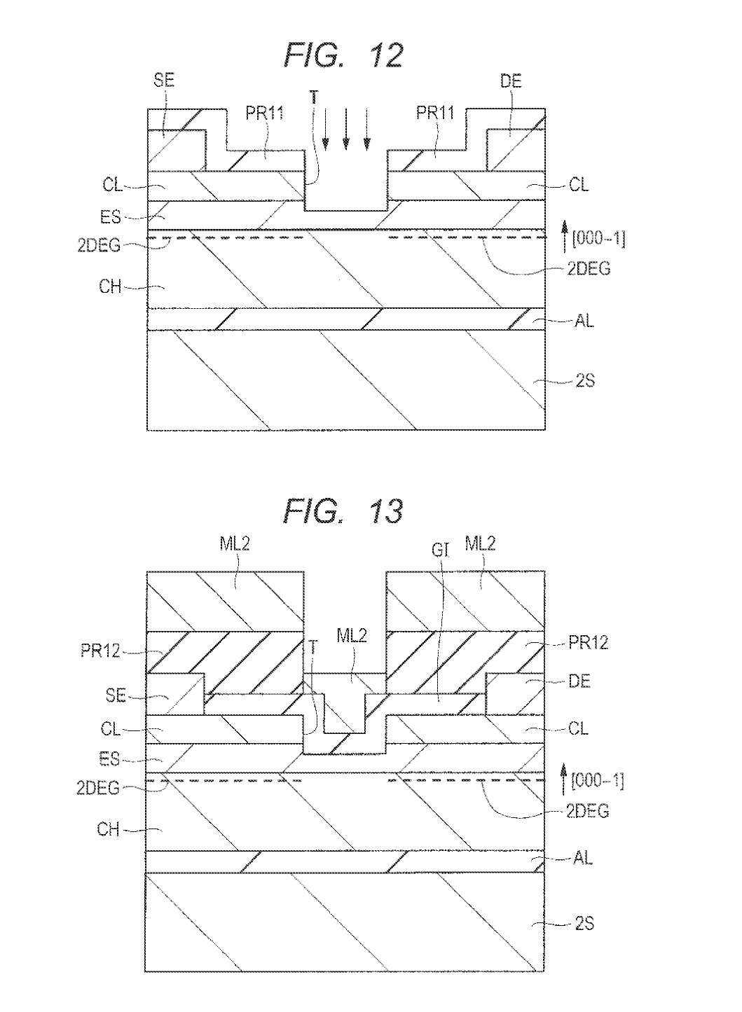

Then, as illustrated in FIG. 11 and FIG. 12, the n-type contact layer (n-type AlGaN layer) CL is separated by removing a central portion of the n-type contact layer (n-type AlGaN layer), in other words, the n-type contact layer (n-type AlGaN layer) CL near the region intended to form the gate electrode GE. First, as illustrated in FIG. 11, a photoresist film PR11 is formed over the n-type contact layer (n-type AlGaN layer) CL including a portion over the source electrode SE and the drain electrode DE and exposed and developed to remove the photoresist film PR11 near the region intended to form the gate electrode GE.

Then, as illustrated in FIG. 12, the n-type contact layer (n-type AlGaN layer) CL is removed by using, for example, a dry etching method while using the photoresist film PR11 as a mask. As an etching gas, a boron chloride (BCl₃) type gas can be used. In this step, the electron supply layer (undoped AlGaN layer) ES below the n-type contact layer (n-type AlGaN layer) CL is exposed. In other words, a trench (also referred to as a recess) T passing through the n-type contact layer (n-type AlGaN layer) CL and reaching as far as the electron supply layer (undoped AlGaN layer) ES is formed. Then, the photoresist film PR11 is removed.

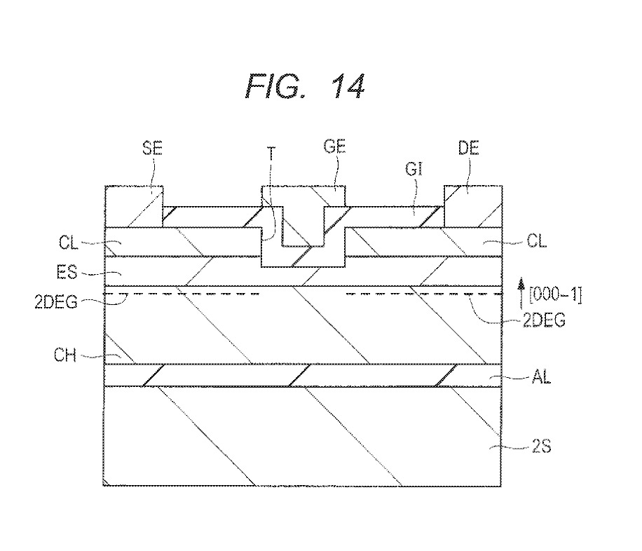

Then, as illustrated in FIG. 13 and FIG. 14, after forming a gate insulation film GI, a gate electrode GE is formed. First, as illustrated in FIG. 13, a gate insulation film GI is formed. As the gage insulation film GI, alumina (aluminum oxide Al₂O₃) can be used. For example, an alumina film is formed as a gate insulation film GI over the source electrode SE, the drain electrode DE, and the n-type contact layer (n-type AlGaN layer) CL including a portion over the inside of the trench T by using, for example, atomic layer deposition (abbreviated as ALD). Then, the gate insulation film GI over the source electrode SE and the drain electrode DE is removed. The gate insulation film GI may be removed also upon forming contact holes over the source electrode SE and the drain electrode DE.

Then, a gate electrode GE is formed over the gate insulation film GI. The gate electrode GE can be formed by using, for example, a lift off method. For example, as illustrated in FIG. 13, a photoresist film PR12 is formed over the gate insulation film GI, and exposed and developed to remove the photoresist film PR12 over the region for forming the gate electrode GE.

Then, a metal film ML2 is formed over the gate insulation film GI including a portion over the photoresist film PR12. Thus, the metal film ML2 is formed directly on the gate insulation film GI in a region for forming the gate electrode GE. On other hand, the metal film ML2 is formed over the photoresist film PR12 in other regions. The metal film ML2 comprises, for example, a stacked film (Ni/Au film) of a nickel (Ni) film and a gold (Au) film formed over the nickel film. Each of the films constituting the metal film ML2 can be formed by using, for example, vacuum vapor deposition.

Then, the photoresist film PR12 is removed. In this step, the metal film ML2 formed over the photoresist film PR12 is also removed together with the photoresist film PR12 to leave the metal film ML2 (gate electrode GE) only in the inside of the trench T and the vicinity thereof (FIG. 14).

By the steps described above, the semiconductor device of this embodiment is completed substantially. In the steps described above, while the gate electrode GE, the source electrode SE, and the drain electrode DE are formed by using the lift off method, the electrodes may be formed also by patterning a metal film.

As described above, since the semiconductor device of this embodiment has a configuration of stacking the channel layer (undoped GaN layer) CH and the electron supply layer (undoped AlGaN layer) ES in the [000-1] direction, (1) normally off operation and (2) improvement of voltage withstanding can be compatibilized easily.

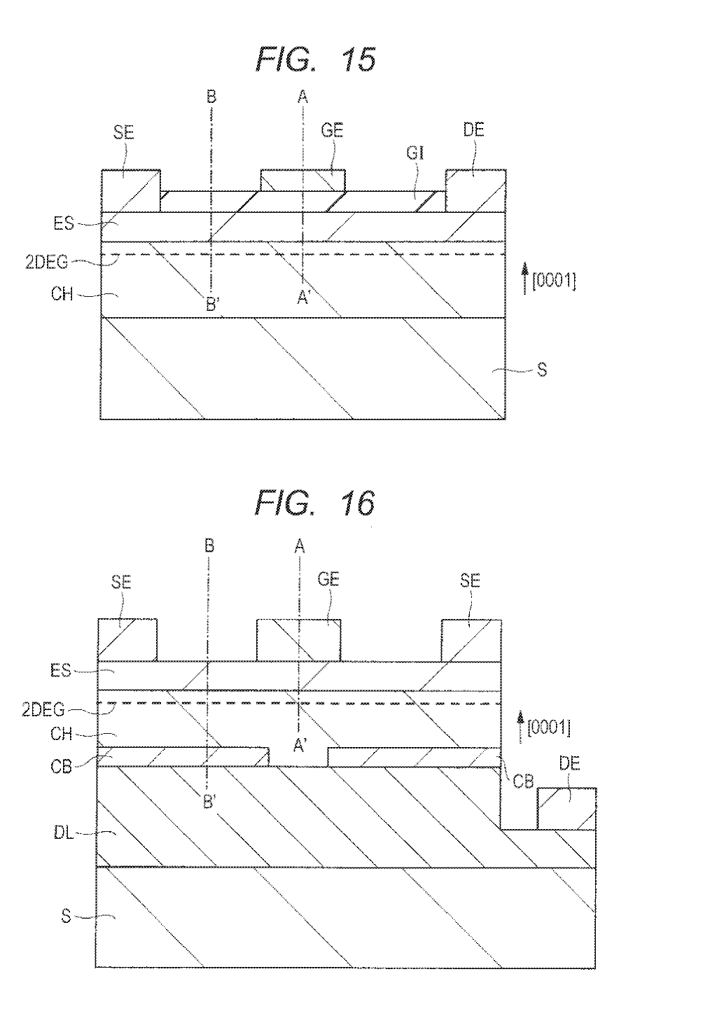

FIG. 15 is a cross sectional view illustrating a configuration of a semiconductor device of Comparative Example 1 of this embodiment. Further, FIG. 16 is a cross sectional view illustrating a configuration of a semiconductor device of Comparative Example 2 of this embodiment.

The semiconductor device of Comparative Example 1 in FIG. 15 is a so-called lateral FET. The semiconductor device has a stack of a channel layer (undoped GaN layer) CH formed over a substrate S and an electron supply layer (undoped AlGaN layer) ES, and a gate electrode GE formed by way of a gate insulation film GI over an electron supply layer (undoped AlGaN layer) ES. A two-dimensional electron gas 2DEG is formed near the interface between the channel layer (undoped GaN layer) CH and the electron supply layer (undoped AlGaN layer) ES. A source electrode SE and a drain electrode DE are formed on both sides of the gate electrode GE over the electron supply layer (undoped AlGaN layer) ES.

The stack of the channel layer (undoped GaN layer) CH and the electron supply layer (undoped AlGaN layer) ES is formed by epitaxial growing in the [0001] direction. In other words, the stack is formed by a so-called gallium (Ga) plane growth mode.

The semiconductor device having the configuration of Comparative Example 1 is a normally on transistor having a negative threshold voltage (Vt) and it is difficult to obtain a normally off operation. For example, the threshold voltage (Vt) is about −4 V to −9 V. Further, in the semiconductor device having the configuration of Comparative Example 1, the threshold voltage (Vt) decreases as the thickness of the gate insulation film GI increases. That is, in the semiconductor device having the configuration of Comparative Example 1, it is extremely difficult to compatibilize the normally off operation and the improvement of the high voltage withstanding.

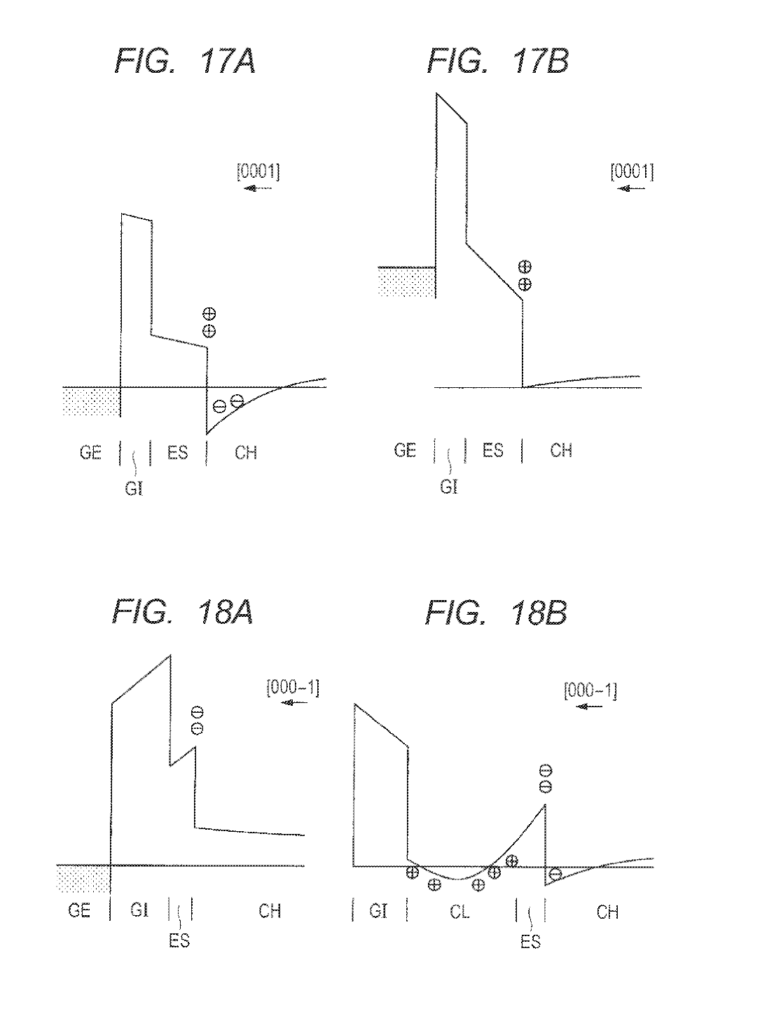

FIG. 17 is a view illustrating a profile of a conduction band energy just below the gate electrode of the semiconductor device of Comparative Example 1 (portion A-A′). The abscissa represents a position just below the gate electrode (portion A-A′) and the ordinate represents an energy level. FIG. 17A shows a profile of a conduction band energy at a gate voltage: Vg=0 V and FIG. 17B shows a profile of a conduction band energy at a gate voltage: Vg=threshold voltage (Vt).

The electron supply layer (undoped AlGaN layer) ES has a lattice constant smaller than that of the channel layer (undoped GaN layer) CH to induce a tensile stress in the electron supply layer (undoped AlGaN layer) ES. Accordingly, polarization is generated in the electron supply layer (undoped AlGaN layer) ES due to a spontaneous polarization effect and a piezoelectric polarization effect. In the configuration of Comparative Example 1, which is epitaxially grown in the [0001] direction and in which the electron supply layer (undoped AlGaN layer) ES and the channel layer (undoped GaN layer) CH are aligned at the Ga plane, positive charges (+σ) are generated at the interface between the electron supply layer (undoped AlGaN layer) ES and the channel layer (undoped GaN layer) CH. In the same manner, negative charges (−σ) are generated at the interface between the electron supply layer (undoped AlGaN layer) ES and the channel layer (undoped GaN layer) CH (FIG. 17A). However, since the negative charges (−σ) are compensated by the energy level at the interface with the gate insulation film GI, they are electrically neutralized.

The plane density σ of the polarized charges can be approximated to the following equation (1):

σ/q≈6.4×10¹³[m⁻²]×x (1).

in which x represents an Al composition of the AlGaN layer as the electron supply layer ES and q represents an elementary charge. For example, when x=0.2 in the Al composition, the plane density σ of the polarized charges is calculated as 1.2×10¹³ [m⁻²]. Accordingly, the two-dimensional electron gas 2DEG is induced near the hetero-interface also in a thermal equilibrium state of the gate voltage: Vg=0 V, to provide normally on operation (FIG. 17A).

On the other hand, in an off state in which the gate voltage is: Vg=threshold voltage (Vt), an electric field is generated inside the gate insulation film GI and the potential energy of the conduction band in the gate insulation film GI increases from the substrate S (channel layer (undoped GaAlN layer)) to the gate electrode GE (FIG. 17B). Since the field strength (σ/∈: ∈ is dielectric constant of gate insulation film) does not depend on the thickness of the gate insulation film GI, the threshold voltage (Vt) decreases as the thickness of the gate insulation film GI increases. Accordingly, it is necessary to decrease the thickness of the gate insulation film GI in order to obtain a desired threshold voltage (Vt). As described above, it is difficult to compatibilize the normally off operation and the increase of the voltage withstanding.

The semiconductor device of Comparative Example 2 in FIG. 16 is a so-called vertical FET. Also in this semiconductor device, it is difficult to compatibilize the normally off operation and the increase of the voltage withstanding. In this case, an n-type drift layer (GaN layer) DL and a p-type current block layer (GaN layer) CB having an opening are formed over the substrate S. The opening forms a current restriction portion. A stack comprising a channel layer (undoped GaN layer) CH and an electron supply layer (undoped AlGaN layer) ES is formed over the p-type current block layer (GaN layer) CB, and a gate electrode GE is formed over the electron supply layer (undoped GaN layer) ES. A two-dimensional electron gas 2DEG is formed near the interface between the channel layer (undoped GaN layer) CH and the electron supply layer (undoped AlGaN layer) ES. Further, a source electrode SE is formed on both sides of the gate electrode GE over the electrode supply layer (undoped AlGaN layer) ES. Further, a drain electrode DE is formed over the lead portion of an n-type drift layer (GaN layer) DL. Also in Comparative Example 2, it is difficult to compatibilize the normally off operation and the increase of the voltage withstanding in the same manner as in Comparative Example 1.

On the contrary, the profile of the conduction band energy of the semiconductor device of this embodiment is as illustrated in FIG. 18. FIG. 18 is a view illustrating the profile of a conduction band energy of the semiconductor device of this embodiment (FIG. 1). The abscissa shows a position and the ordinate shows an energy level. FIG. 18A shows the profile of a conduction band energy just below the gate electrode (A-A′ portion) and FIG. 18B shows the profile of the conduction band energy just below a portion situated between the gate electrode and the source electrode (drain electrode) (portion B-B′).

The electron supply layer (undoped AlGaN layer) ES has a lattice constant smaller than that of the channel layer (undoped GaN layer) CH to induce a tensile stress in the electron supply layer (undoped AlGaN layer) ES. Accordingly, polarization is generated in the electron supply layer (undoped AlGaN layer) ES due to a spontaneous polarization effect and a piezoelectric polarization effect. However, in this embodiment, since the crystal plane is overturned, negative charges (−σ) are generated at the interface between the electron supply layer (undoped AlGaN layer) ES and the channel layer (undoped GaN layer) CH. In other words, in the semiconductor device of this embodiment in which the electron supply layer (undoped AlGaN layer) ES and the channel layer (undoped GaN layer) CH are aligned at the N-plane, negative charges (−σ) are generated at the interface between the electron supply layer (undoped AlGaN layer) ES and the channel layer (undoped GaN layer) CH. In the same manner, positive charges (+σ) are generated at the interface between the electron supply layer (undoped AlGaN layer) ES and the channel layer (undoped GaN layer) CH (FIG. 18A). However, since the positive charges (+σ) are compensated by the energy level at interface with the gate insulation film GI, they are electrically neutralized.

In view of the equation (1), at x=0.2 in the Al composition of the AlGaN layer as the electron supply layer ES, the surface density σ of the polarized charges is calculated as 1.2×10¹³ [m⁻²]. Accordingly, in the thermal equilibrium state at a gate voltage: Vg=0 V, a two-dimensional electron gas (channel) 2DEG just below the gate electrode (portion A-A′) is depleted to enable normally off operation (FIG. 18A). On the other hand, in the off state at the gate voltage: Vg=threshold voltage (Vt), since the direction of the electric field generated inside the gate insulation film GI is also opposite to that of Comparative Example 1, the conduction band potential energy in the gate insulation film GI decreases from the substrate 2S (channel layer) (undoped GaN layer) CH to the gate electrode GE. Since the field strength (σ/∈: ∈ is dielectric constant of the gate insulation film) does not depend on the thickness of the gate insulation film GI, the threshold voltage (Vt) increases as the thickness of the gate insulation film GI increases. As described above, in the semiconductor device of this embodiment, it is easy to compatibilize the normally off operation and the increase of the withstanding voltage.

Further, in a region excluding a portion just below the gate electrode (portion B-B′), n-type impurities in the contact layer (n-type AlGaN layer) CL are ionized to form positive charges. In this case, the surface density of the n-type impurities in the n-type contact layer (n-type AlGaN layer) CL is set, for example, to 5×10¹³ cm⁻² so as to be larger than the surface density σ of the negative charges. Further, since the band gap of the channel layer (undoped GaN layer) CH is smaller than that of the electron supply layer (undoped AlGaN layer) ES, a two-dimensional electron gas 2DEG is generated at the interface between the electron supply layer (undoped AlGaN layer) ES and the channel layer (undoped GaN layer) CH to reduce the on resistance (FIG. 18B).

### Modification

In the configuration illustrated in FIG. 1, the n-type impurity layer (n-type semiconductor layer: also referred to as an n-type semiconductor region) (n-type contact layer (n-type AlGaN layer) CL) was provided to a portion of the AlGaN layer (n-type contact layer (n-type AlGaN layer) CL and the electron supply layer (undoped AlGaN layer) ES), but an n-type impurity layer (n-type contact layer (n-type AlGaN layer) CL) may also be disposed to a portion of the channel layer (undoped GaN layer) CH.

For example, after stacking a channel layer (undoped GaN layer) CH, an n-type contact layer (n-type GaN layer) CL, and an electron supply layer (undoped AlGaN layer) ES, a trench T may be formed by removing the electron supply layer (undoped AlGaN layer) ES and the n-type contact layer (n-type GaN layer) CL.

Further, the embodiment in FIG. 1 shows an example of a gate electrode configuration of a so-called MIS (metal-insulator semiconductor) type in which the gate electrode GE is disposed by way of the gate insulation film GI over the electron supply layer (undoped AlGaN layer) ES, but a so-called Schottky type gate electrode configuration in which a gate electrode GE is disposed directly on the electron supply layer (undoped AlGaN layer) ES may also be adopted.

For aligning the electron supply layer (undoped AlGaN layer) ES and the channel layer (undoped GaN layer) CH over the N-plane, it may be considered to use a so-called growth mode over the N plane (nitrogen plane) of crystallographically growing the electron supply layer (undoped AlGaN layer) ES in the [000-1] direction over the channel layer (undoped GaN layer) CH. However, it is difficult to obtain a mirror plane growth over the N plane of the channel layer (undoped GaN layer) CH since the etching rate over the N-plane of the channel layer (undoped GaN layer) CH is higher than that over the Ga plane. As a result, no satisfactory crystals can be obtained by the growth mode over the N-plane.

On the other hand, in this embodiment, a stack in which the electron supply layer (undoped AlGaN layer) ES and the channel layer (undoped GaN layer) CH are aligned over the N-plane can be obtained by growing the crystal in the Ga plane mode that can provide good crystals and inverting the stack upside down. In particular, a stack of high planarity can be formed by growing crystals in the Ga-plane mode and peeling the sacrificial layer (GaN layer) SL from the n-type contact layer (n-type AlGaN layer) CL by using, for example, a laser lift off method.

### Second Embodiment

In the first embodiment, while a gate electrode of a so-called recessed gate structure is used, a gate electrode of a planar gate structure is used in this embodiment.

### [Description of Structure]

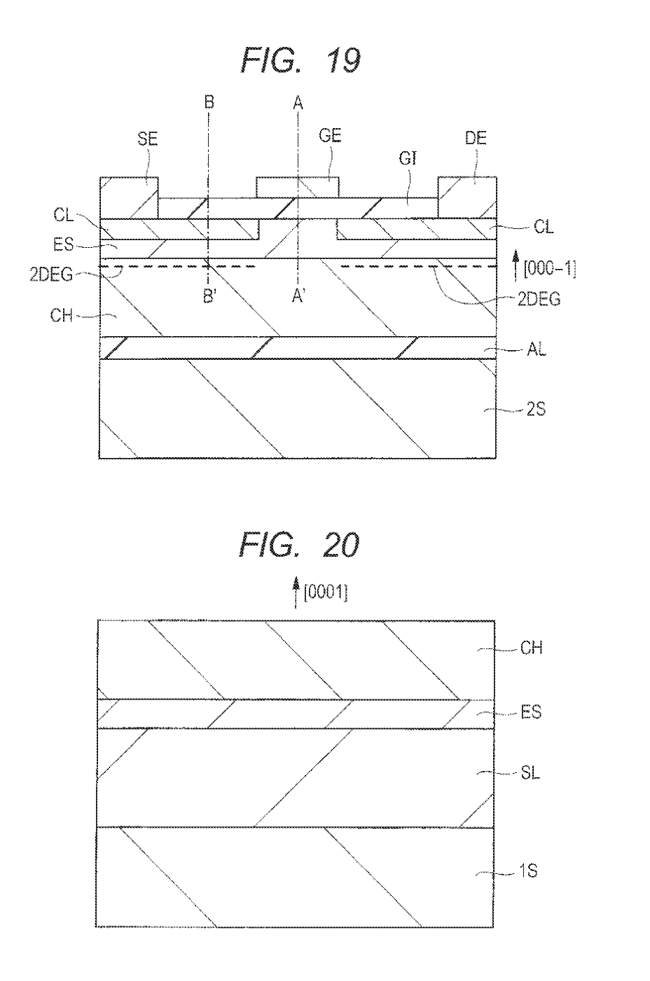

FIG. 19 is a cross sectional view illustrating a configuration of a semiconductor device of this embodiment. The semiconductor device illustrated in FIG. 19 is a field effect transistor using nitride semiconductors. It is also referred to as a high electron mobility transistor (HEMT).

As illustrated in FIG. 19, in the semiconductor device of this embodiment, a stack comprising a channel layer (also referred to as an electron travel layer) CH, an electron supply layer ES, and an n-type contact layer CL is disposed by way of a bonding layer AL over a support substrate 2S. The stack comprises nitride semiconductors. The electron supply layer ES comprises a nitride semiconductor having a band gap larger than that of the channel layer CH.

In this embodiment, an undoped GaN layer is used as a channel layer CH, an undoped AlGaN layer is used as an electron supply layer ES, and an n-type AlGaN layer is used as a contact layer CL. A two-dimensional electron gas 2DEG is generated near the interface between the electron supply layer ES and the channel layer CH on the side of the channel layer CH.

The junction plane between the electron supply layer (undoped AlGaN layer) ES and the channel layer (undoped GaN layer) CH is the Ga plane ((0001) plane)). The direction from the channel layer (undoped GaN layer) CH to the electron supply layer (undoped AlGaN layer) ES is a [000-1] direction. In other words, the direction from the junction plane (plane that generates the two-dimensional electron gas 2DEG) to the electron supply layer (undoped AlGaN layer) ES is the [000-1] direction.

Further, a gate electrode GE is disposed by way of a gate insulation film GI over the electron supply layer (undoped AlGaN layer) ES exposed through an opening of the n-type contact layer (n-type AlGaN layer) CL. In other words, the n-type contact layer (n-type AlGaN layer) CL is disposed by way of the gate insulation film GI on both sides of the gate electrode GE, and the electron supply layer (undoped AlGaN layer) ES is disposed below the gate electrode GE by way of the gate insulation film GI. A source electrode SE and a drain electrode DE are disposed on both sides of the gate electrode GE respectively over the n-type contact layer (n-type AlGaN layer) CL.

An interlayer insulation layer (not illustrated) is disposed over the gate electrode GE. A conductive film (plug, not illustrated) filled in a contact hole formed in the interlayer insulation film is disposed over the source electrode SE and the drain electrode DE.

### [Description of Manufacturing Method]

Then, a method of manufacturing a semiconductor device of this embodiment is to be described with reference to FIG. 20 to FIG. 25, which makes the configuration of the semiconductor device more definite. FIG. 20 to FIG. 25 are cross sectional views illustrating manufacturing steps of the semiconductor device of this embodiment.

As illustrated in FIG. 20, a substrate 1S comprising, for example, gallium nitride (GaN) is provided as the substrate (also referred to as a substrate for growing) 1S.

Then, a sacrificial layer SL is formed by way of a nucleation layer (not illustrated) over the substrate 1S. The sacrificial layer SL comprises, for example, a GaN layer. The sacrificial layer (GaN layer) SL of about 1 μm thickness is deposited over the substrate 1S comprising, for example, gallium nitride (GaN) by using MOCVD.

Then, an electron supply layer ES is formed over the sacrificial layer (GaN layer) SL. An undoped AlGaN layer of about 50 nm thickness is deposited by using, for example, MOCVD. The AlGaN layer has a compositional ratio shown by Al_{0.2}Ga_{0.8}N. Then, a channel layer CH is formed over the electron supply layer (undoped AlGaN layer) ES. For example, an undoped GaN layer of about 1 μm thickness is deposited by using MOCVD.

The grown film formed by using the MOCVD described above is referred to as an epitaxial layer (epitaxial film). A stack comprising the sacrificial layer (GaN layer) SL, the electron supply layer (undoped AlGaN layer) ES, and the channel layer (undoped GaN layer) CH is formed in a growth mode over the Ga plane parallel with the [0001] crystal axis direction. In other words, respective layers are grown successively over the Ga plane parallel with the [0001] crystal axis direction.

Specifically, GaN is grown over the Ga plane ((0001) plane) of the substrate 1S comprising gallium nitride (GaN) in the [0001] direction to form the sacrificial layer (GaN layer) SL. Then, undoped AlGaN is grown over the Ga plane ((0001) plane) of the sacrificial layer (GaN layer) SL in the [0001] direction to form the electron supply layer (undoped AlGaN layer) ES. Then, undoped GaN is grown over the Ga plane ((0001) plane) of the electron supply layer (undoped AlGaN layer) ES in the [0001] direction to form the channel layer (undoped GaN layer) CH.

The interface (junction plane) between the electron supply layer (undoped AlGaN layer) ES and the channel layer (undoped GaN layer) CH is the Ga plane ((0001) plane) and the direction from the interface to the channel layer (undoped GaN layer) CH is the [0001] direction.

As described above, by forming each of the layers of the stack comprising the sacrificial layer (GaN layer) SL, the electron supply layer (undoped AlGaN layer) ES, and the channel layer (undoped GaN layer) CH) in the growth mode over the Ga plane parallel with the crystal axis direction, a stack comprising more planer epitaxial layers with less unevenness can be obtained.

While the lattice constant is different between AlGaN and GaN, a stack of good crystal quality with less occurrence of dislocation can be obtained by setting the total film thickness of the AlGaN to a critical film thickness or less.

As the substrate 1S, substrates other than the substrate comprising gallium nitride (GaN) may also be used. However, when a substrate comprising gallium nitride (GaN) is used, a stack of good crystal quality with less occurrence of dislocation can be grown. Crystal defects such as the dislocation described above cause a leak current. Accordingly, the leak current can be decreased by suppressing the crystal defects and the off withstanding voltage of a transistor can be improved.

As the nucleation layer (not illustrated) over the substrate 1S, a super lattice layer formed by repeatingly stacking a stacked film (AlN/GaN film) comprising a gallium nitride (GaN) layer and an aluminum nitride (AlN) layer can be used.

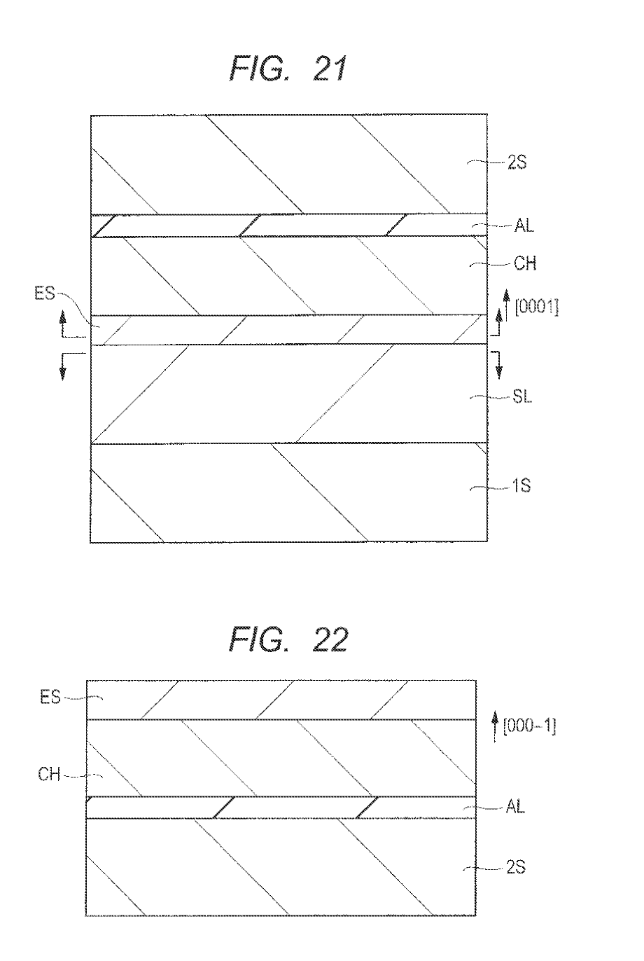

Then, as illustrated in FIG. 21, a bonding layer AL is formed over the (0001) plane of the channel layer (undoped GaN layer) CH, and a support substrate 2S is mounted thereover. As the bonding layer AL, a coating type insulation film comprising, for example, HSQ can be used. Further, as the support substrate 2S, a substrate comprising, for example, silicon (Si) can be used.

For example, after coating an HSQ precursor over the channel layer (undoped GaN layer) CH and mounting the support substrate 2S, a heat treatment at about 200° C. is applied. Thus, HSQ is hardened and the channel layer (undoped GaN layer) CH and the support substrate 2S can be bonded by way of the bonding layer AL as illustrated in FIG. 6. When HSQ is used as the bonding layer AL, it can withstand a thermal load up to about 900° C.

Then, the sacrificial layer (GaN layer) SL and the substrate 1S are peeled from the interface between the sacrificial layer (GaN layer) SL and the electron supply layer (undoped AlGaN layer) ES. As the peeling method, a laser lift off method can be used, for example, in the same manner as in the first embodiment. Thus, a stacked structure in which the electron supply layer (undoped AlGaN layer) ES and the channel layer (undoped GaN layer) CH are stacked and, further, the bonding layer AL and the support substrate 2S are stacked thereover is formed.

Then, as illustrated in FIG. 22, the stacked structure is turned upside down such that the electron supply layer (undoped AlGaN layer) ES of the stacked structure is situated at the upper surface. Thus, the stack comprising the channel layer (undoped GaN layer) CH and the electron supply layer (undoped AlGaN layer) ES is disposed by way of the bonding layer AL over the support substrate 2S. As has been described above, the junction plane between the electron supply layer (undoped AlGaN layer) ES and the channel layer (undoped GaN layer) CH is the Ga plane ((0001) plane). The direction from the junction plane to the electron supply layer (undoped AlGaN layer) ES is the [000-1] direction.

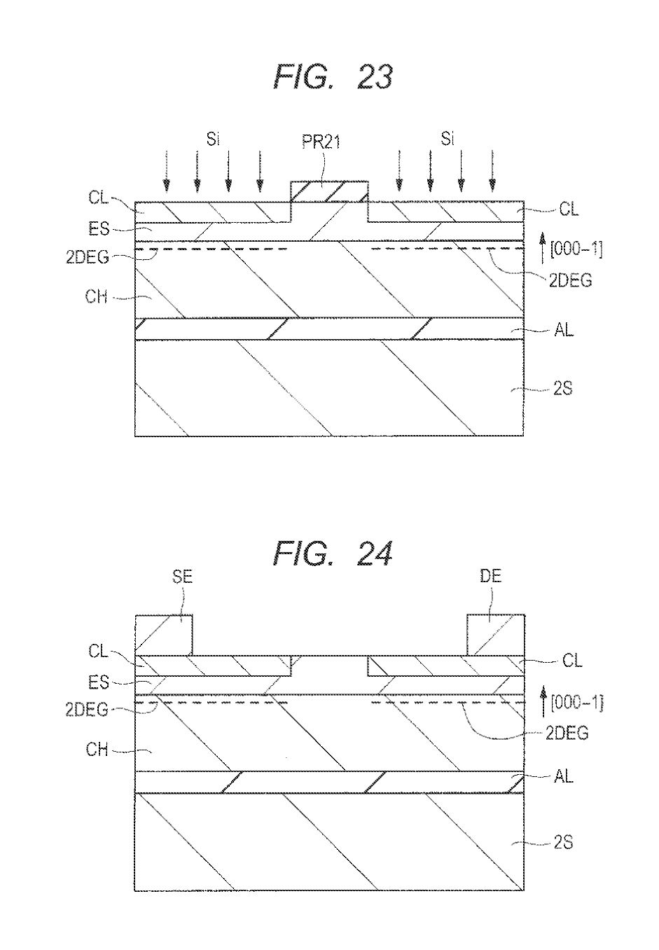

Then, as illustrated in FIG. 23, an n-type contact layer (n-type AlGaN layer) CL is formed by ion implantation. First, as illustrated in FIG. 23, a photoresist film PR21 is formed over the electron supply layer (undoped AlGaN layer) ES and exposed and developed, so that the photoresist film PR21 at a region other than the region intended to form the gate electrode GE is removed. Then, n-type impurities are ion implanted into an upper layer portion of the electron supply layer (undoped AlGaN layer) ES. Thus, an n-type contact layer (n-type AlGaN layer) CL is formed on both sides of the region intended to form the gate electrode GE over the electron supply layer (undoped AlGaN layer) ES. For example, as the n-type impurity, Si (silicon) is used and the concentration (impurity concentration) thereof is, for example, about 1×10¹⁹/cm³. The thickness of the n-type contact layer (n-type AlGaN layer) CL is, for example, about 30 nm. Then, the photoresist film PR2 is removed. Then, a heat treatment (annealing) is applied, for example, in a nitrogen atmosphere to activate the n-type impurities (Si in this embodiment) in the n-type contact layer (n-type AlGaN layer) CL. By the heat treatment, the electron concentration in the n-type contact layer (n-type AlGaN layer) CL is, for example, about 2×10¹⁹/cm³.

Then, as illustrated in FIG. 24, a source electrode SE and a drain electrode DE are formed on both sides of a region intended to form the gate electrode GE over the n-type contact layer (n-type AlGaN layer) CL. The source electrode SE and the drain electrode DE can be formed by using, for example, a lift off method in the same manner as in the first embodiment. Then, a heat treatment (alloying treatment) is applied to the support substrate 2S in the same manner as in the first embodiment. By the heat treatment, the source electrode SE and the channel layer (undoped GaN layer) CH to which the two-dimensional electron gas 2DEG is formed (undoped GaN layer) CH can be in ohmic contact. In the same manner, the drain electrode DE and the channel layer (undoped GaN layer) CH can be in ohmic contact. That is, the source electrode SE and the drain electrode DE are in a state connected electrically to the two-dimensional electron gas 2DEG respectively.

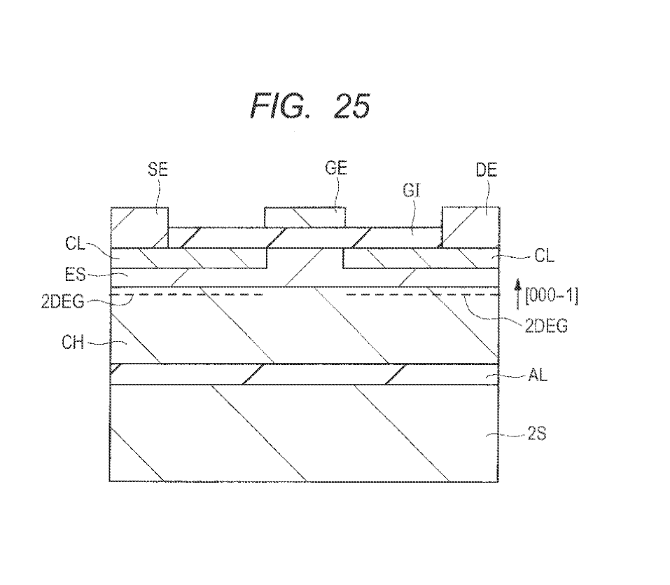

Then, as illustrated in FIG. 25, after forming a gate insulation film GI, a gate electrode GE is formed. First, the gate insulation film GI is formed in the same manner as in the first embodiment. For example, an alumina film is formed as the gate insulation film GI over the source electrode SE, the drain electrode DE, the electron supply layer (undoped AlGaN layer) ES, and the n-type contact layer (n-type AlGaN layer) CL by using atomic layer deposition. Then, the gate insulation film GI over the source electrode SE and the drain electrode DE is removed. The gate insulation film GI may be removed also upon forming contact holes over the source electrode SE and the drain electrode DE.

Then, a gate electrode GE is formed over the gate insulation film GI. The gate electrode GE can be formed by using, for example, a lift off method in the same manner as in the first embodiment.

By the steps described above, the semiconductor device of this embodiment is substantially completed. In the steps described above, while the gate electrode GE, the source electrode SE, and the drain electrode DE were formed by using the lift off method, the electrodes may be formed also by patterning a metal film.

As described above, in the semiconductor device of this embodiment, since the channel layer (undoped GaN layer) CH and the electron supply layer (undoped AlGaN layer) ES are stacked successively in the [000-1] direction, (1) the normally off operation and (2) the increase of the voltage withstanding can be compatibilized easily as described specifically in the first embodiment.

That is, the profile of the conduction band energy of the semiconductor device of this embodiment is identical with that of the first embodiment (FIG. 18). Accordingly, as has been described specifically in the first embodiment, negative charges (−σ) are generated at the interface between the electron supply layer (undoped AlGaN layer) ES and the channel layer (undoped GaN layer) CH. Accordingly, in a thermal equilibrium state at a gate voltage: Vg=0 V, the two-dimensional electron gas (channel) 2DEG just below the gate electrode (portion A-A′) is depleted to enable the normally off operation (refer to FIG. 18A). Further, in an off state at a gate voltage: Vg=threshold voltage (Vt), the potential energy of the conduction band in the gate insulation film GI decreases from the side of the substrate 2S (channel layer (undoped GaN layer) CH) to the gate electrode GE. Since the electric field strength (σ/∈: ∈ is dielectric constant of the gate insulation film) does not depend on the thickness of the gate insulation film GI, the threshold voltage (Vt) increases as the thickness of the gate insulation film GI increases. As described above, in the semiconductor device of this embodiment, the normally off operation and the increase of the withstanding voltage can be compatibilized easily.

Further, in a region excluding a portion just below the gate electrode (portion B-B′), n-type impurities in the n-type contact layer (n-type AlGaN layer) CL are ionized to form positive charges and the two-dimensional electron gas 2DEG is generated at the interface between the electron supply layer (undoped AlGaN layer) ES and the channel layer (undoped GaN layer) CH to reduce the on resistance (refer to FIG. 18B).

Further, in this embodiment, since the step of forming the trench T is not necessary, the threshold voltage (Vt) can be controlled more easily than in the case of the first embodiment.

### Modification

In the embodiment illustrated in FIG. 19, the n-type impurity layer (n-type contact layer (n-type AlGaN layer) CL) was provided to a portion of the AlGaN layer (n-type contact layer (n-type AlGaN layer) CL and the electron supply layer (undoped AlGaN layer) ES), but the n-type impurity layer (n-type contact layer (n-type AlGaN layer) CL) may also be disposed to a portion of the channel layer (undoped GaN layer) CH.

For example, upon ion implantation illustrated in FIG. 23, an n-type contact layer (n-type AlGaN layer) CL may also be formed on both sides of a region intended to form an upper layer portion of a channel layer (undoped GaN layer) CH intended to form the gate electrode GE by ion implantation of n-type impurities.

Further, the embodiment illustrated in FIG. 19 shows an example of a gate electrode configuration of a so-called MIS (metal-insulator-semiconductor) type in which the gate electrode GE is disposed by way of the gate insulation film GI over the electron supply layer (undoped AlGaN layer) ES, but a gate electrode configuration of a so-called Schottky type in which a gate electrode GE is disposed directly on the electron supply layer (undoped AlGaN layer) ES may also be adopted.

### Third Embodiment

In the first and the second embodiments, while description has been made to an example of a so-called lateral FET, description is to be made in third to sixth embodiments to a so-called vertical FET. A semiconductor device of this embodiment is to be described specifically with reference to the drawings.

### [Description of Structure]

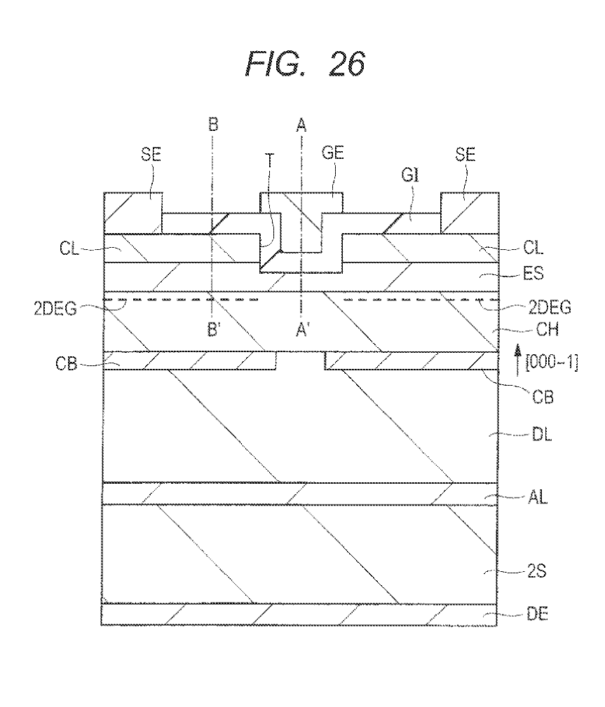

FIG. 26 is a cross sectional view illustrating a configuration of a semiconductor device of this embodiment. The semiconductor device illustrated in FIG. 26 is a field effect transistor by using nitride semiconductors. It is also referred to as a high electron mobility transistor (HEMT).

As illustrated in FIG. 26, in the semiconductor device of this embodiment, a stack comprising an n-type drift layer DL, a current block layer CB, a channel layer (also referred to as an electron travel layer) CH, an electron supply layer ES, and an n-type contact layer CL is disposed by way of a bonding layer AL over a support substrate 2S. The stack comprises nitride semiconductors. The electron supply layer ES comprises a nitride semiconductor having a band gap larger than that of the channel layer CH. The current block layer CB has an opening portion (isolation portion) at a position corresponding to the gate electrode GE. The opening of the current block layer CB forms a current constriction portion.

In this embodiment, an n-type GaN layer is used as an n-type drift layer DL and a p-type GaN layer is used as a current block layer CB. An undoped GaN layer is used as a channel layer CH, an undoped AlGaN layer is used as an electron supply layer ES, and an n-type AlGaN layer is used as a contact layer CL. A two-dimensional electron gas 2DEG is generated near the interface between the electron supply layer ES and the channel layer CH on the side of the channel layer CH.

The junction plane between the electron supply layer (undoped AlGaN layer) ES and the channel layer (undoped GaN layer) CH is a Ga plane ((0001) plane)). The direction from the channel layer (undoped GaN layer) CH to the electron supply layer (undoped AlGaN layer) ES is a [000-1] direction. In other words, the direction from the junction plane (plane that generates the two-dimensional electron gas 2DEG) to the electron supply layer (undoped AlGaN layer) ES is a [000-1] direction.

The gate electrode GE is disposed by way of a gate insulation film GI in the inside of a trench T that passes through the n-type contact layer (n-type AlGaN layer) CL and allows an electron supply layer (undoped AlGaN layer) ES to be exposed from the surface thereof. A source electrode SE is disposed on both sides of the gate electrode GE over the n-type contact layer (n-type AlGaN layer) CL. The drain electrode DE is disposed at the rear face of the support substrate 2S.

The semiconductor device of such a configuration is referred to as a vertical FET in which carriers travel from the channel layer (undoped GaN layer) CH through an opening (current constriction portion) to the n-type drift layer (n-type GaN layer) DL in a direction vertical to the support substrate 2S. FET operation is performed by modulating the carrier concentration of the two-dimensional electron gas 2DEG by a gate voltage.

An interlayer insulation layer (not illustrated) is disposed over the gate electrode GE. A conductive film (plug, not illustrated) filled in a contact hole formed in the interlayer insulation layer is disposed over the source electrode SE.

### [Description of Manufacturing Method]

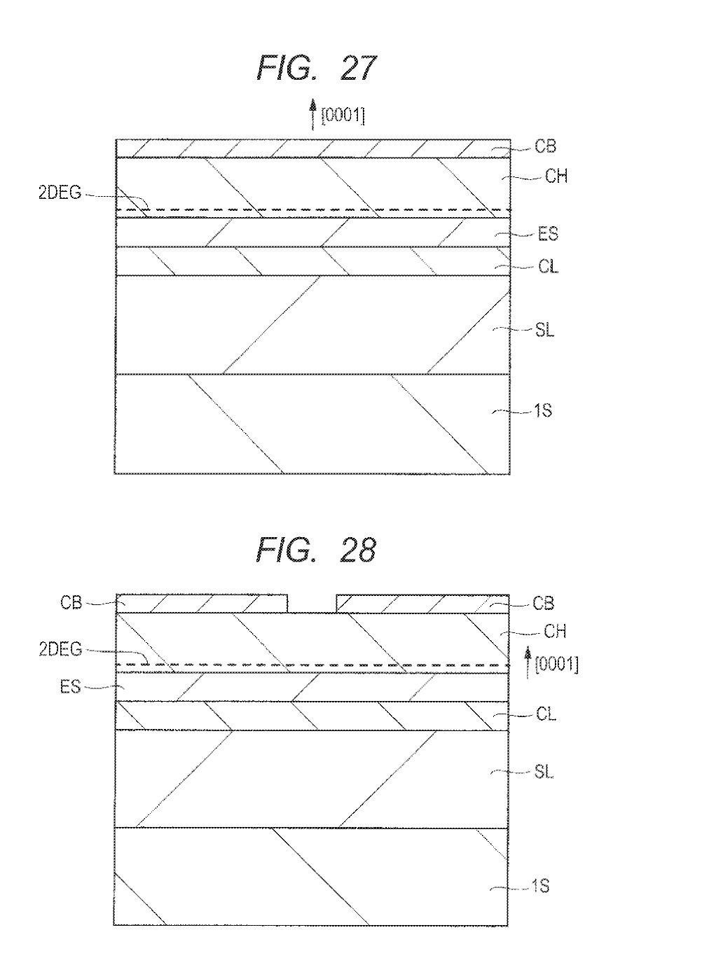

Then, a method of manufacturing a semiconductor device of this embodiment is to be described with reference to FIG. 27 to FIG. 32, which makes the configuration of the semiconductor device more definite. FIG. 27 to FIG. 32 are cross sectional views illustrating manufacturing steps of the semiconductor device of this embodiment.

As illustrated in FIG. 27, a substrate 1S comprising, for example, gallium nitride (GaN) is provided as the substrate (also referred to as a substrate for growing) 1S.

Then, a sacrificial layer SL is formed by way of a nucleation layer (not illustrated) over the substrate 1S. The sacrificial layer SL comprises, for example, a GaN layer. The sacrificial layer SL (GaN layer) of about 1 μm thickness is deposited over the substrate 1S comprising, for example, gallium nitride (GaN) by using MOCVD.

Then, an n-type contact layer CL is formed over the sacrificial layer (GaN layer) SL. For example, an n-type AlGaN layer of about 50 nm thickness is deposited by using MOCVD. The AlGaN layer has a compositional ratio represented by Al_{0.2}Ga_{0.8}N. For example, Si (silicon) is used as the n-type impurity and the concentration (impurity concentration) thereof is, for example, about 1×10¹⁹/cm³. Then, an electron supply layer ES is formed over the n-type contact layer (n-type AlGaN layer) CL. For example, an undoped AlGaN layer of about 20 nm thickness is deposited over the n-type contact layer (n-type AlGaN layer) CL by using MOCVD. The AlGaN layer has a compositional ratio represented by Al_{0.2}Ga_{0.8}N. Then, a channel layer CH is formed over the electron supply layer (undoped AlGaN layer) ES. For example, an undoped GaN layer of about 0.1 μm thickness is deposited by using MOCVD. Then, a p-type current block layer (p-type impurity layer, also referred to as a p-type semiconductor region) CB is formed over the channel layer CH (undoped GaN layer). For example, a p-type GaN layer of about 0.5 μm thickness is deposited by using MOCVD. For example, Mg (magnesium) is used as the p-type impurity and the concentration (impurity concentration) thereof is, for example, about 1×10¹⁹/cm³.

The grown film formed by using MOCVD described above is referred to as an epitaxial layer (epitaxial film). A stack comprising the sacrificial layer (GaN layer) SL, the n-type contact layer (n-type AlGaN layer) CL, the electron supply layer (undoped AlGaN layer) ES, the channel layer (undoped GaN layer) CH, and the p-type current block layer (p-type GaN layer) CB is formed in a growth mode over the Ga plane parallel with the [0001] crystal axis direction. In other words, respective layers are grown successively over the Ga plane parallel with the [0001] crystal axis direction.

Specifically, GaN is grown over the Ga plane ((0001) plane) of the substrate 1S comprising gallium nitride (GaN) in the [0001] direction to form the sacrificial layer (GaN layer) SL. Then, n-type AlGaN is grown over the Ga plane ((0001) plane) of the sacrificial layer (GaN layer) SL in the [0001] direction to form the n-type contact layer (n-type AlGaN layer) CL. Then, undoped AlGaN is grown in the [0001] direction over the Ga plane [0001] plane of the n-type contact layer (n-type AlGaN layer) Cl to form an electron supply layer (undoped AlGaN layer) ES. Then, undoped GaN is grown over the Ga plane ((0001) plane) of the electron supply layer (undoped AlGaN layer) ES in the [0001] direction to form a channel layer (undoped GaN layer) CH. Then, p-type GaN is grown over the Ga plane ((0001) plane) of the channel layer (undoped GaN layer) CH in the [0001] direction to form a current block layer (p-type GaN layer) CB.

A two-dimensional electron gas (two-dimensional electron gas layer) 2DEG is generated (formed) near the interface between the electron supply layer (undoped AlGaN layer) ES and the channel layer (undoped GaN layer) CH. The plane that generates the two-dimensional electron gas 2DEG, that is, the junction plane (interface) between the electron supply layer (undoped AlGaN layer) ES and the channel layer (undoped GaN layer) CH is the Ga plane ((0001) plane) and the direction from the junction plane (plane that generates the two-dimensional electron gas 2DEG) to the channel layer (undoped GaN layer) CH is the [0001] direction.

As described above, by forming each of the layers of the stack (the n-type contact layer (n-type AlGaN layer) CL, the electron supply layer (undoped AlGaN layer) ES, the channel layer (undoped GaN layer) CH, and the p-type current block layer (p-type GaN layer) CB in the growth mode over the Ga plane parallel with the [0001] crystal axis direction, a stack comprising more planar epitaxial layers with less unevenness can be obtained.

While the lattice constant is different between AlGaN and GaN, a stack of good crystal quality with less occurrence of dislocation can be obtained by setting the total film thickness of the AlGaN to a critical film thickness or less.

As the substrate 1S, substrates other than the substrate comprising gallium nitride (GaN) may also be used. However, when a substrate comprising gallium nitride (GaN) is used, a stack of good crystal quality with less occurrence of dislocation can be grown. Crystal defects such as the dislocation described above cause leak current. Accordingly, leak current can be decreased by suppressing the crystal defects and the off withstanding voltage of the transistor can be improved.

As the nucleation layer (not illustrated) over the substrate 1S, a super lattice layer formed by repeatingly stacking stack films (AlN/GaN film) each comprising a gallium nitride (GaN) layer and an aluminum nitride (AlN) layer can be used.

Then, a heat treatment (annealing) is applied, for example, in a nitrogen atmosphere to activate p-type impurities (Mg in this embodiment) in the current block layer (p-type GaN layer) CB. By the heat treatment, hole concentration in the current block layer (p-type GaN layer) CB is, for example, about 2×10¹⁸/cm³.

Then, as illustrated in FIG. 28, an opening is formed to the current block layer (p-type GaN layer) by removing a central portion of the current block layer (p-type GaN layer) CB, in other words, a current block layer (p-type GaN layer) CB near a region intended to form a gate electrode GE. For example, a photoresist film (not illustrated) covering a region intended to form the gate electrode GE is formed over the current block layer (p-type GaN layer) CB and the current block layer (p-type GaN layer) CB is removed by using, for example, dry etching. As an etching gas, a boron chloride (BCl₃) type gas can be used. By the step, an opening is formed in the current block layer (p-type GaN layer) CB and the channel layer (undoped GaN layer) CH is exposed from the bottom thereof. Then, the photoresist film (not illustrated) is removed.

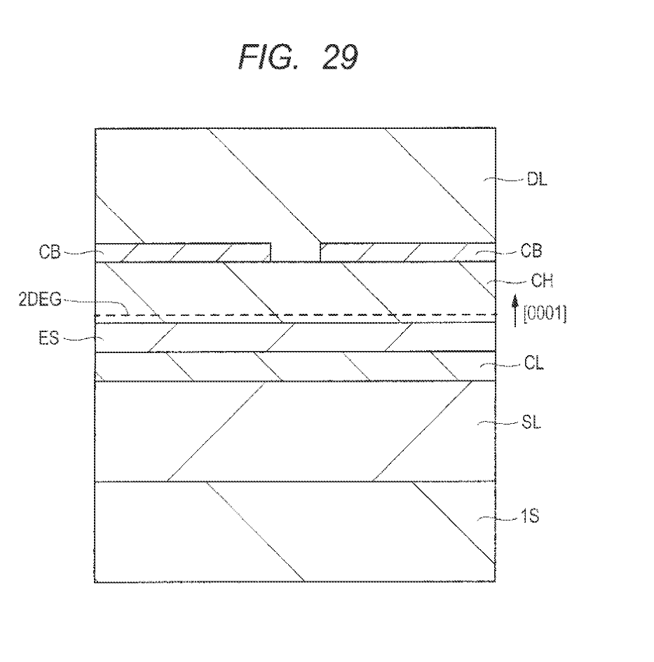

Then, as illustrated in FIG. 29, an n-type drift layer (n-type GaN layer) DL is formed over the current block layer (p-type GaN layer) CB including the exposed portion of the channel layer (undoped GaN layer) CH. For example, an n-type drift layer (n-type GaN layer) DL of about 10 μm thickness is grown over the current block layer (p-type GaN layer) CB including the inside of the opening by using MOCVD. For example, Si (silicon) is used as the n-type impurity and the concentration (impurity concentration) thereof is, for example, about 5×10¹⁶/cm³. Epitaxial growing over the current block layer (p-type GaN layer) CB including the inside of the opening as described above is referred to as filling re-growth.

As the current block layer CB, a stacked film comprising a p-type GaN layer and an AlN layer (aluminum nitride layer: about 0.01 μm thickness) thereover may also be used. In this case, an opening is formed in the stacked film and an n-type drift layer (n-type GaN layer) DL is grown over the current block layer (stacked film) CB including the inside of the opening by using MOCVD (filling re-growth). In this case, an n-type drift layer (n-type GaN layer) DL is epitaxially grown from the exposed portion of the channel layer (undoped GaN layer) CH in the opening and the n-type drift layer (n-type GaN layer) DL is epitaxially grown over the AlN layer in other portion. The growing rate of the n-type GaN layer over the AlN layer is smaller compared with that over the undoped GaN layer. Accordingly, film is deposited preferentially in the opening. Further, after the opening has been filled completely with the n-type GaN layer, growth proceeds in the lateral direction on both sides of the opening. Thus, the planarity of the surface of the n-type drift layer (n-type GaN layer) DL can be improved upon filling re-growth. The n-type drift layer (n-type GaN layer) DL filled in the opening forms a current constriction portion (aperture).

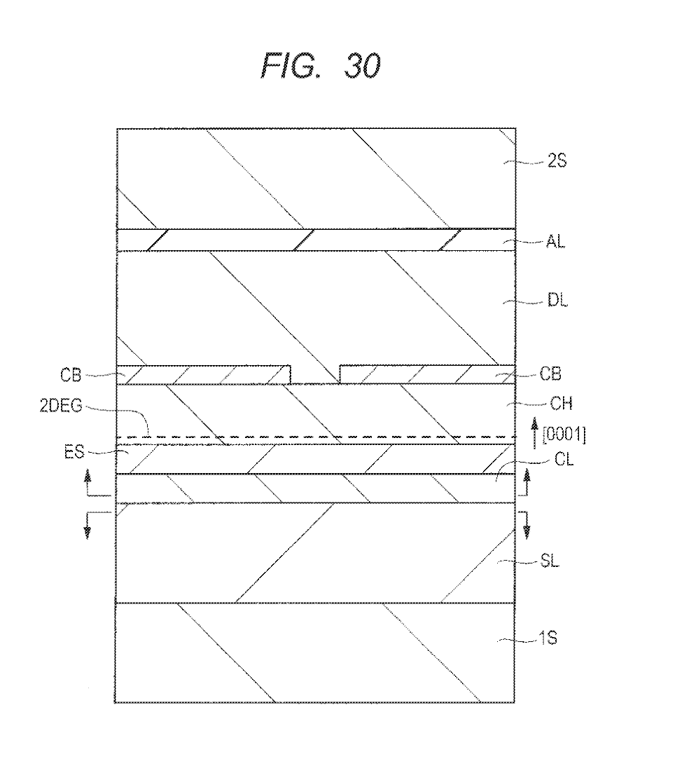

Then, as illustrated in FIG. 30, a bonding layer AL is formed over the (0001) plane of the n-type drift layer (n-type GaN layer) DL and a support substrate 2S is mounted thereover. For example, a solder layer comprising an alloy of Au (gold) and tin (Sn) can be used as the bonding layer AL. Further, a metal film (metallized film) may also be provided above and below the solder layer. For example, a stacked film (Ti/Al) comprising a titanium (Ti) film and an aluminum (Al) film formed over the titanium film is formed as a metal film over the (0001) plane of the n-type drift layer (n-type GaN layer) DL, and a solder layer is formed thereover. Alternatively, a stacked film (Ti/Pt/Au) comprising a titanium (Ti) film, a platinum (Pt) film formed on the titanium film, and a gold (Au) film formed on the platinum film is formed as the metal film over the support substrate 2S. As the support substrate 2S, a substrate comprising silicon (Si) can be used.

Then, the solder layer as the bonding layer AL and the metal film of the support substrate 2S are opposed and the n-type drift layer (n-type GaN layer) DL and the support substrate 2S are fused by way of the solder layer (bonding layer AL).

Then, the sacrificial layer (GaN layer) SL and the substrate 1S are peeled from the interface between the sacrificial layer (GaN layer) SL and the n-type contact layer (n-type AlGaN layer) CL. As the peeling method, a laser lift off method can be used in the same manner as in the first embodiment.

Thus, a stacked structure in which the n-type contact layer (n-type GaN layer) CL, the electron supply layer (undoped AlGaN layer) ES, the channel layer (undoped GaN layer) CH, the current block layer (p-type GaN layer) CB, and the n-type drift layer (n-type GaN layer) DL are stacked and, further, the bonding layer AL and the support substrate 2S are stacked thereover is formed.

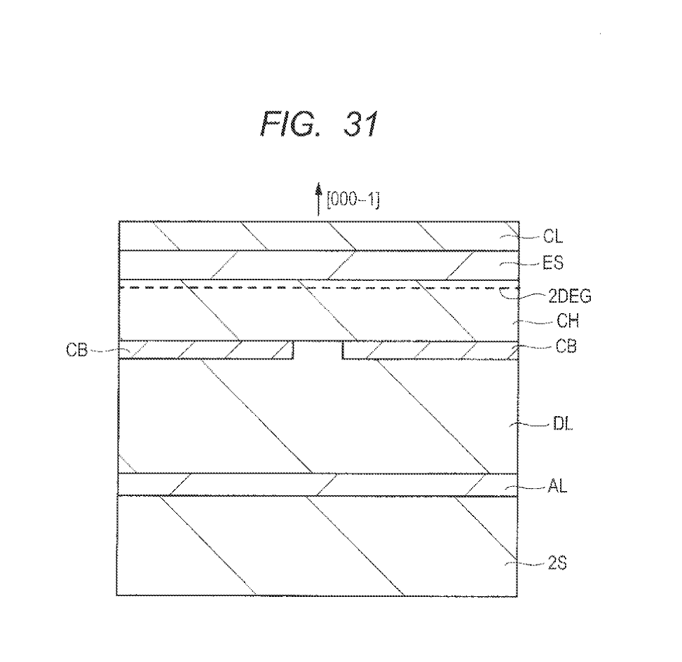

Then, as illustrated in FIG. 31, the stacked structure is turned upside down such that the n-type contact layer (n-type AlGaN layer) CL of the stacked structure is situated to the upper surface. Thus, the stack is disposed by way of the bonding layer Al over the support substrate 2S. As has been described above, the junction plane between the electron supply layer (undoped AlGaN layer) ES and the channel layer (undoped GaN layer) CH is the Ga plane ((0001) plane). Then, the direction from the junction plane (plane that generates two-dimensional electron gas 2DEG) to the electron supply layer (undoped AlGaN layer) ES is the [000-1] direction.

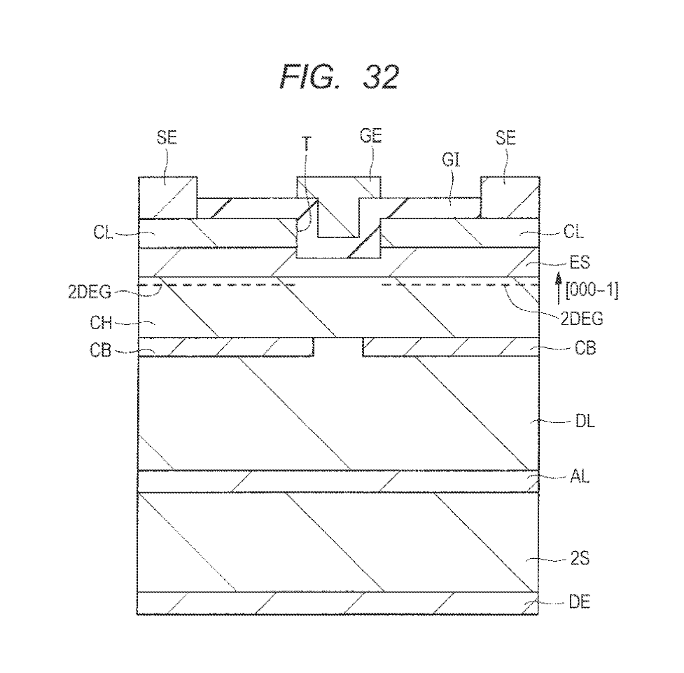

Then, as illustrated in FIG. 32, a source electrode SE is formed over the n-type contact layer (n-type AlGaN layer) CL. The source electrode SE can be formed by using a lift off method in the same manner as in the first embodiment. For example, a photoresist film (not illustrated) having an opening in a region for forming the source electrode SE is formed. Then, a metal film is formed over the n-type contact layer (n-type AlGaN layer) CL including a portion over the photoresist film and the metal film over the photoresist is removed together with the photoresist film. Thus, the source electrode SE can be formed over the n-type contact layer (n-type AlGaN layer) CL.

Then, a heat treatment (alloying treatment) is applied to the support substrate 2S. For examples, a heat treatment about at 600° C. and for one minute is applied in a nitrogen atmosphere as the heat treatment. By the heat treatment, the source electrode SE and the channel layer (undoped GaN layer) CH to which the two-dimensional electron gas 2DEG is generated can be in ohmic contact.

Then, in the same manner as in the first embodiment, after forming the trench T, a gate insulation film GI is formed and, further, a gate electrode GE is formed. That is, the n-type contact layer (n-type AlGaN layer) CL is removed by using, for example, dry etching to form the trench T that passes through the n-type contact layer (n-type AlGaN layer) CL and allows the electron supply layer (undoped AlGaN layer) ES to be exposed. Then, for example, an alumina film is formed as the gate insulation film GI over the electron supply layer (undoped AlGaN layer) ES including a portion over the source electrode SE by using ALD. Then, the gate insulation film GI over the source electrode SE is removed. Then, the gate electrode GE is formed over the gate insulation film GI in the inside of the trench T by using, for example, a lift off method.

Then, the support substrate 2S is turned upside down such that the rear face of the support substrate 2S is situated to the upper surface (FIG. 32). For example, a drain electrode DE is formed by forming a metal film over the support substrate 2S. For example, a stacked film (Ti/Al) comprising a titanium (Ti) film and an aluminum (Al) film formed on the titanium film can be used as the metal film. The film can be formed by using, for example, vacuum vapor deposition.

With the steps described above, the semiconductor device of this embodiment is completed substantially. Then, while the gate electrode GE and the source electrode SE were formed in the step described above by using the lift off method, the electrodes may also be formed by patterning the metal film.

As described above, in the semiconductor device of this embodiment, since the channel layer (undoped GaN layer) CH and the electron supply layer (undoped AlGaN layer) ES are stacked sequentially in the [000-1] direction, (1) the normally off operation and (2) the increase of the withstanding voltage can be compatibilized easily as has been described specifically for the first embodiment.

That is, the profile of the conduction band energy of the semiconductor device of this embodiment is identical with that of the first embodiment (FIG. 18). Accordingly, as has been described specifically in the first embodiment, negative charges (−σ) are generated at the interface between the electron supply layer (undoped AlGaN layer) ES and the channel layer (undoped GaN layer) CH. Accordingly, in a thermal equilibrium state at a gate voltage: Vg=0 V, the two-dimensional electron gas (channel) 2DEG just below the gate electrode (portion A-A′) is depleted to enable the normally off operation (refer to FIG. 18A). Further, in an off state at a gate voltage: Vg=threshold voltage (Vt), the potential energy of the conduction band in the gate insulation film GI decreases from the side of the substrate 2S (channel layer (undoped GaN layer) CH) to the gate electrode GE. Since the electric field strength (σ/∈: ∈ is dielectric constant of the gate insulation film) does not depend on the thickness of the gate insulation film GI, the threshold voltage (Vt) increases as the thickness of the gate insulation film GI increases. As described above, in the semiconductor device of this embodiment, the normally off operation and the increase of the withstanding voltage can be compatibilized easily.

Further, in a region excluding a portion just below the gate electrode (B-B′ portion), n-type impurities in the n-type contact layer (n-type AlGaN layer) CL are ionized to form positive charges, and a two-dimensional electron gas 2DEG is generated at the interface between the electron supply layer (undoped AlGaN layer) ES and the channel layer (undoped GaN layer) CH to reduce the on resistance (refer to FIG. 18B).

Further, in this embodiment, since the opening (current constriction portion) is formed in the current block layer (p-type GaN layer) CB, carriers can be introduced efficiently to the drain. Further, according to this embodiment, the current block layer (p-type GaN layer) CB and the opening thereof (current constriction portion) can also be formed easily.

### Modification

In the embodiment illustrated in FIG. 26, the n-type impurity layer (n-type contact layer (n-type AlGaN layer) CL) was provided to a portion of the AlGaN layer (n-type contact layer (n-type AlGaN layer) CL and the electron supply layer (undoped AlGaN layer) ES), but the n-type impurity layer (n-type contact layer (n-type AlGaN layer) CL) may be disposed also to a portion of the channel layer (undoped GaN layer) CH.

For example, after stacking the channel layer (undoped GaN layer) CH, the n-type contact layer (n-type GaN layer) CL, and the electron supply layer (undoped AlGaN layer) ES, the electron supply layer (undoped AlGaN layer) ES and the n-type contact layer (n-type GaN layer) CL may be removed to form the trench T.

Further, the embodiment illustrated in FIG. 26 shows an example of a so-called MIS (metal-insulator-semiconductor) type gate electrode configuration in which the gate electrode GE is disposed by way of the gate insulation film GI over the electron supply layer (undoped AlGaN layer) ES, but a so-called Schottky type gate electrode configuration in which the gate electrode GE is disposed directly on the electron supply layer (undoped AlGaN layer) ES may also be adopted.

### Fourth Embodiment

A semiconductor device of this embodiment is to be described below specifically with reference to the drawings.

### [Description of Structure]

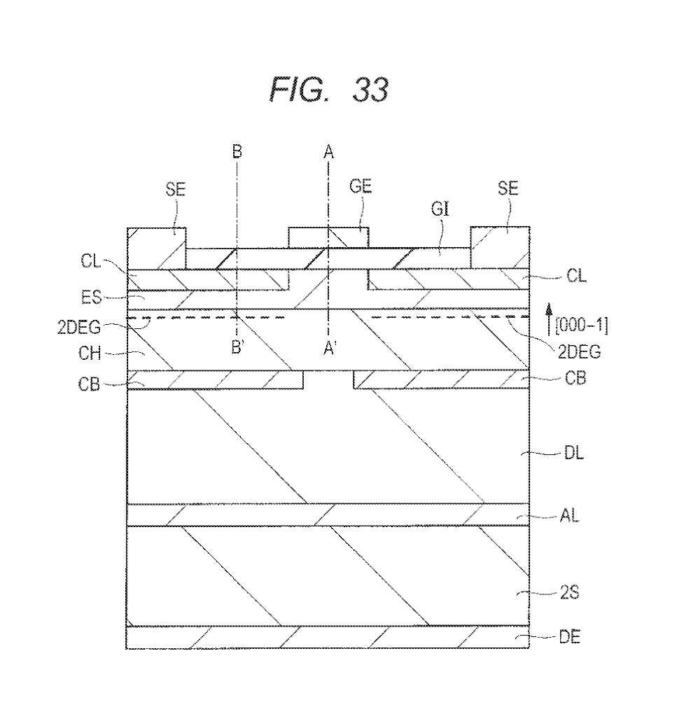

FIG. 33 is a cross sectional view illustrating a configuration of a semiconductor device of this embodiment. The semiconductor device illustrated in FIG. 33 is a field effect transistor using nitride semiconductors. This is also referred to as a high electron mobility transistor (HEMT).

As illustrated in FIG. 33, in the semiconductor device of this embodiment, a stack comprising an n-type drift layer DL, a current block layer CB, a channel layer (also referred to as an electron travel layer) CH, an electron supply layer ES, and an n-type contact layer CL is disposed by way of a bonding layer AL over a support substrate 2S. The stack comprises nitride semiconductors. The electron supply layer ES comprises a nitride semiconductor having a band gap larger than that of the channel layer CH.

The current block layer CB has an opening at a position corresponding to the gate electrode GE. The opening portion of the current block layer CB forms a current constriction portion.

In this embodiment, an n-type GaN layer is used as the n-type drift layer DL and a p-type GaN layer is used as the current block layer CB. An undoped GaN layer is used as the channel layer CH, an undoped AlGaN layer is used as the electron supply layer ES, and an n-type AlGaN layer is used as the contact layer CL. A two-dimensional electron gas 2DEG is generated near the interface between the electron supply layer ES and the channel layer CH on the side of the channel layer CH.

The junction plane between the electron supply layer (undoped AlGaN layer) ES and the channel layer (undoped GaN layer) CH is a Ga plane ((0001) plane)). Then, the direction from the channel layer (undoped GaN layer) CH to the electron supply layer (undoped AlGaN layer) ES is a [000-1] direction. In other words, the direction from the junction plane (plane that generates the two-dimensional electron gas 2DEG) to the electron supply layer (undoped AlGaN layer) ES is the [000-1] direction.

Further, a gate electrode GE is disposed by way of a gate insulation film GI over the electron supply layer (undoped AlGaN layer) ES exposed through the opening of the n-type contact layer (n-type AlGaN layer) CL. In other words, the n-type contact layer (n-type AlGaN layer) CL is disposed by way of the gate insulation film GI on both sides of the gate electrode GE, and the electron supply layer (undoped AlGaN layer) ES is disposed by way of the gate insulation film GI below the gate electrode GE. A source electrode SE is disposed over the n-type contact layer (n-type AlGaN layer) CL on both sides of the gate electrode GE. Further, a drain electrode DE is disposed on the rear face of the support substrate 2S.

The semiconductor device of such a configuration is referred to as a vertical FET in which carriers travel from the channel layer (undoped GaN layer) CH through the opening (current constriction portion) to the n-type drift layer (n-type GaN layer) DL in a direction vertical to the support substrate 2S. FET operation is performed by modulating the carrier concentration of the two-dimensional electron gas 2DEG by a gate voltage.

An interlayer insulation layer (not illustrated) is disposed over the gate electrode GE. Further, a conductive film (plug, not illustrated) filled in a contact hole formed in the interlayer insulation layer is disposed over the source electrode SE.

### [Description of Manufacturing Method]

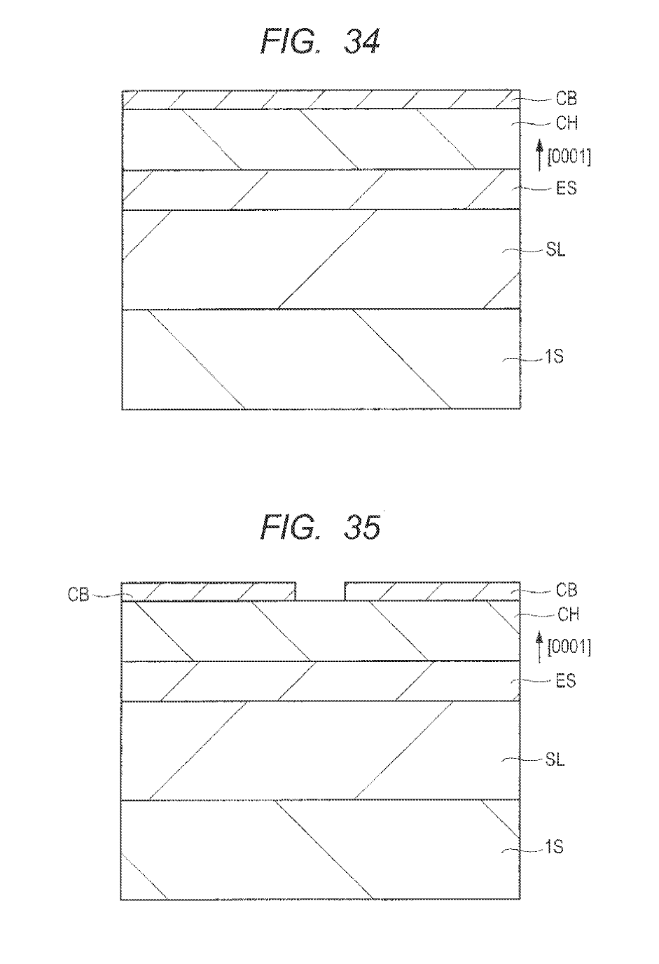

Then, a method of manufacturing the semiconductor device of this embodiment is to be described with reference to FIG. 34 to FIG. 40, and the configuration of the semiconductor device is made more definite. FIG. 34 to FIG. 40 are cross sectional views illustrating manufacturing steps of the semiconductor device of this embodiment.

As illustrated in FIG. 34, a substrate 1S comprising, for example, gallium nitride (GaN) is provided as the substrate (also referred to as a substrate for growing) 1S.

Then, a sacrificial layer SL is formed by way of a nucleation layer (not illustrated) over the substrate 1S. The sacrificial layer SL comprises, for example, a GaN layer. For example, the sacrificial layer (GaN layer) SL of about 1 μm thickness is deposited over the substrate 1S comprising gallium nitride (GaN) by using MOCVD.

Then, an electron supply layer ES is formed over the sacrificial layer (GaN layer) SL. An undoped AlGaN layer of about 20 nm thickness is deposited by using, for example, MOCVD. The AlGaN layer has a compositional ratio shown by Al_{0.2}Ga_{0.8}N. Then, a channel layer CH is formed over the electron supply layer (undoped AlGaN layer) ES. An undoped GaN layer of about 0.1 μm thickness is deposited by using, for example, MOCVD. Then, a p-type current block layer CB is formed over the channel layer CH (undoped GaN layer). A p-type GaN layer of about 0.5 μm thickness is deposited by using, for example, MOCVD. For example, Mg (magnesium) is used as a p-type impurity and the concentration (impurity concentration) thereof is, for example, about 1×10¹⁹/cm³.

The grown film formed by using MOCVD described above is referred to as an epitaxial layer (epitaxial film). The stack comprising the sacrificial layer (GaN layer) SL, the electron supply layer (undoped AlGaN layer) ES, the channel layer (undoped GaN layer) CH, and the p-type current block layer (p-type GaN layer) CB is formed in a growth mode over the Ga plane parallel with the crystal axis direction. In other words, respective layers are grown successively over the Ga plane parallel with the [0001] crystal axis direction.

Specifically, GaN is grown over the Ga plane ((0001) plane) of the substrate 1S comprising gallium nitride (GaN) in the [0001] direction to form the sacrificial layer (GaN layer) SL. Then, undoped AlGaN is grown over the Ga plane ((0001) plane) of the sacrificial layer (GaN layer) SL in the [0001] direction to form the electron supply layer (undoped AlGaN layer) ES. Then, undoped GaN is grown over the Ga plane ((0001) plane) of the electron supply layer (undoped AlGaN layer) ES in the [0001] direction to form the channel layer (undoped GaN layer) CH. Then, p-type GaN is grown over the Ga plane ((0001) plane) of the channel layer (undoped GaN layer) CH in the [0001] direction to form the current block layer (p-type GaN layer) CB.

The interface (junction plane) between the electron supply layer (undoped AlGaN layer) ES and the channel layer (undoped GaN layer) CH is the Ga plane ((0001) plane) and the direction from the interface (junction plane) to the channel layer (undoped GaN layer) CH is the [0001] direction.

As described above, by forming each of the layers of the stack (sacrificial layer (GaN layer) SL, electron supply layer (undoped AlGaN layer) ES, channel layer (undoped GaN layer) CH, and p-type current block layer (p-type GaN layer) CB) in the growth mode over the Ga plane parallel with the [0001] crystal axis direction, a stack comprising more planar epitaxial layers with less unevenness can be obtained.

While the lattice constant is different between AlGaN and GaN, a stack of good crystal quality with less occurrence of dislocation can be obtained by setting the total film thickness of AlGaN to a critical film thickness or less.

As the substrate 1S, substrates other than the substrate comprising gallium nitride (GaN) may also be used. When a substrate comprising gallium nitride (GaN) is used, a stack of good crystal quality with less occurrence of dislocation can be grown. Crystal defects such as the dislocation described above cause leak current. Accordingly, leak current can be decreased by suppressing the crystal defects and the off withstanding voltage of a transistor can be improved.

As the nucleation layer (not illustrated) over the substrate 1S, a super lattice layer formed by repeatingly stacking a stacked film (AlN/GaN film) comprising a gallium nitride (GaN) layer and an aluminum nitride (AlN) layer can be used.

Then, a heat treatment (annealing) is applied, for example, in a nitrogen atmosphere to activate p-type impurities (Mg in this embodiment) in the current block layer (p-type GaN layer) CB. By the heat treatment, a hole concentration in the current block layer (p-type GaN layer) CB is, for example, about 2×10¹⁸/cm³.

Then, as illustrated in FIG. 35, an opening is formed to a current block layer (p-type GaN layer) CB by removing a central portion of the current block layer (p-type GaN layer) CB, in other words, a current block layer (p-type GaN layer) CB near a region intended to form a gate electrode GE. For example, a photoresist film (not illustrated) covering a region intended to form the gate electrode GE is formed over the current block layer (p-type GaN layer) CB and the current block layer (p-type GaN layer) CB is removed by using dry etching. As an etching gas, a boron chloride (BCl₃) type gas can be used. By the step, an opening is formed in the current block layer (p-type GaN layer) CB and a channel layer (undoped GaN layer) CH is exposed from the bottom thereof. Then, the photoresist film (not illustrated) is removed.

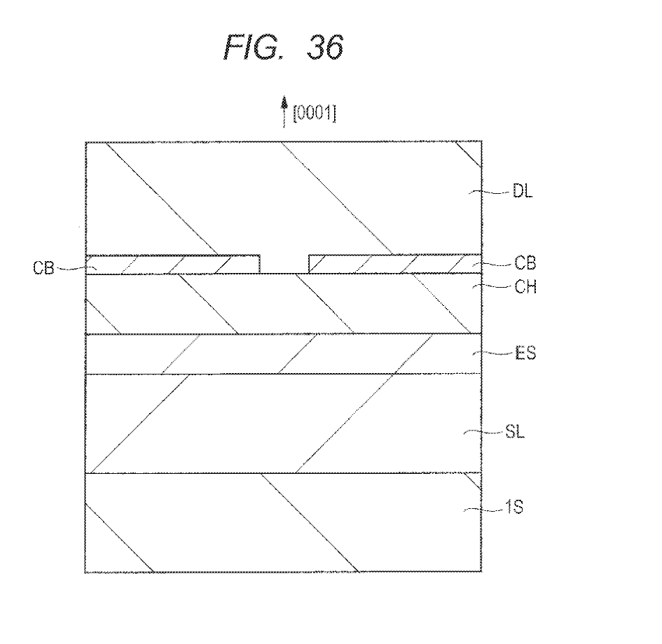

Then, as illustrated in FIG. 36, an n-type drift layer (n-type GaN layer) DL is formed over the current block layer (p-type GaN layer) CB including the exposed portion of a channel layer (undoped GaN layer) CH. For example, an n-type drift layer (n-type GaN layer) DL of about 10 μm thickness is grown over the current block layer (p-type GaN layer) CB including the inside of the opening by using MOCVD. Si (silicon) is used, for example, as the n-type impurities and the concentration (impurity concentration) thereof is, for example, about 5×10¹⁶/cm³. Epitaxial growing over the current block layer (p-type GaN layer) CB including the inside of the opening as described above is referred to as filling re-growth.

As the current block layer CB, a stacked film comprising a p-type GaN layer and an AlN layer (aluminum nitride layer: about 0.01 μm thickness) thereover may also be used. In this case, an opening is formed in the stacked film and an n-type drift layer (n-type GaN layer) DL is grown over the current block layer (stacked film) CB including the inside of the opening by using MOCVD (filling re-growth). In this case, the n-type drift layer (n-type GaN layer) DL is epitaxially grown from the exposed portion of the channel layer (undoped GaN layer) CH in the opening and the n-type drift layer (n-type GaN layer) DL is epitaxially grown over the AlN layer in other portion. The growing rate of the n-type GaN layer over the AlN layer is lower compared with that over the undoped GaN layer. Accordingly, a film is deposited preferentially in the opening. After the opening has been filled completely with the n-type GaN layer, growth proceeds in the lateral direction on both sides of the opening. Thus, the planarity of the surface of the n-type drift layer (n-type GaN layer) DL can be improved upon filling re-growth. The n-type drift layer (n-type GaN layer) DL filled in the opening forms a current constriction portion.

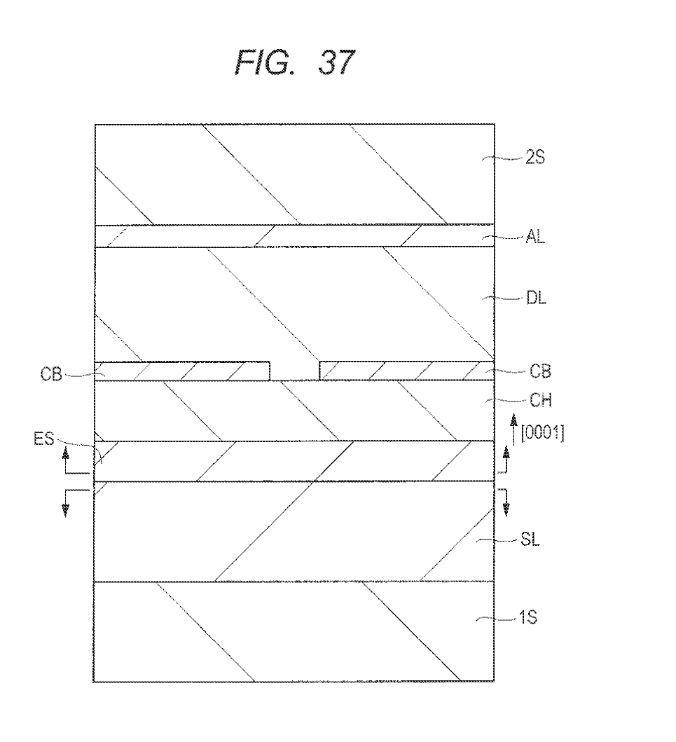

Then, as illustrated in FIG. 37, a bonding layer AL is formed over the (0001) plane of the n-type drift layer (n-type GaN layer) DL and a support substrate 2S is mounted thereover. For example, an Ag (silver) paste can be used as the bonding layer AL. Further, a metal film (metallized film) may also be provided above and below the Ag (silver) paste. For example, a stacked film (Ti/Al) comprising a titanium (Ti) film and an aluminum (Al) film formed over the titanium film is formed as a metal film over the (0001) plane of the n-type drift layer (n-type GaN layer) DL, and the Ag (silver) paste is formed thereover. Alternatively, a stacked film (Ti/Pt/Au) comprising a titanium (Ti) film, a platinum (Pt) film formed on the titanium film, and a gold (Au) film formed on the platinum film is formed as the metal film over the support substrate 2S. As the support substrate 2S, a substrate comprising silicon (Si) can be used.

Then, the Ag (silver) paste as the bonding layer AL and the metal film of the support substrate 2S are opposed, and the n-type drift layer (n-type GaN layer) DL and the support substrate 2S are fused by way of the Ag (silver) paste (bonding layer AL).

Then, the sacrificial layer (GaN layer) SL and the substrate 1S are peeled from the interface between the sacrificial layer (GaN layer) SL and the electron supply layer (undoped AlGaN layer) ES. As the peeling method, a laser lift off method can be used in the same manner as in the first embodiment.

Thus, a stacked structure in which the electron supply layer (undoped AlGaN layer) ES, the channel layer (undoped GaN layer) CH, the current block layer (p-type GaN layer) CB, and the n-type drift layer (n-type GaN layer) DL are stacked and, further, the bonding layer AL and the support substrate 2S are stacked thereover is formed.

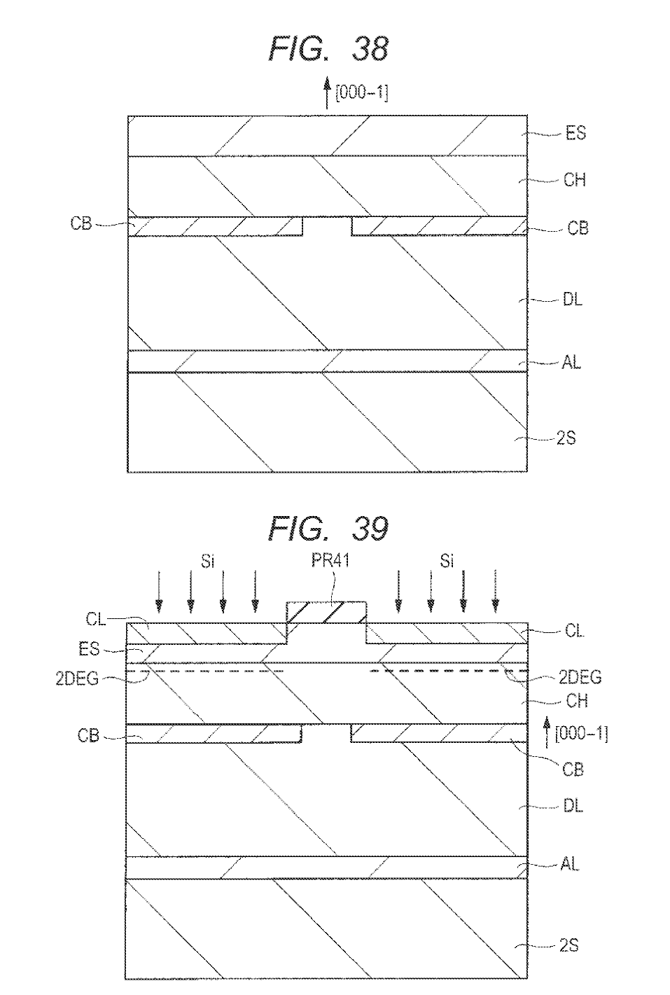

Then, as illustrated in FIG. 38, the stacked structure is turned upside down such that the electron supply layer (undoped AlGaN layer) ES of the stacked structure is situated to the upper surface. Thus, the stack is disposed by way of the bonding layer AL over the support substrate 2S. As has been described above, the junction plane between the electron supply layer (undoped AlGaN layer) ES and the channel layer (undoped GaN layer) CH is the Ga plane ((001) plane). The direction from the junction plane (plane that generates a two-dimensional electron gas 2DEG) to the electron supply layer (undoped AlGaN layer) ES is the [000-1] direction.

Then, as illustrated in FIG. 39, an n-type contact layer (n-type AlGaN layer) CL is formed by ion implantation. First, a photoresist film PR41 is formed to a region intended to form a gate electrode GE over the electron supply layer (undoped AlGaN layer) ES. Then, n-type impurities are ion implanted into the upper layer portion of the electron supply layer (undoped AlGaN layer) ES by using the photoresist film PR41 as a mask. Thus, an n-type contact layer (n-type AlGaN layer) CL is formed in the upper layer portion of the electron supply layer (undoped AlGaN layer) ES on both sides of a region intended to form the gate electrode GE. For example, Si (silicon) is used as the n-type impurity, and the concentration (impurity concentration) thereof is, for example, about 1×10¹⁹/cm³. The thickness of the n-type contact layer (n-type AlGaN layer) CL is, for example, about 30 nm. Then, the photoresist film PR41 is removed. Then, a heat treatment (annealing) is applied, for example, in a nitrogen atmosphere to activate the n-type impurities (Si in this embodiment) in the n-type contact layer (n-type AlGaN layer) CL. By the heat treatment, the electron concentration in the n-type contact layer (n-type AlGaN layer) CL is, for example, about 2×10¹⁹/cm³.

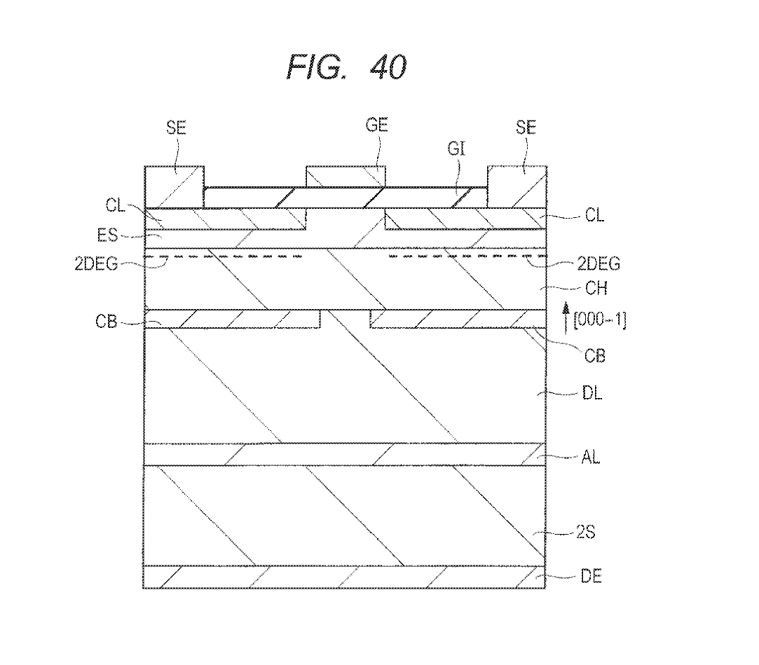

Then, as illustrated in FIG. 40, a source electrode SE is formed over the n-type contact layer (n-type AlGaN layer) CL on both sides of a region intended to form the gate electrode GE. The source electrode SE can be formed by using a lift off method in the same manner as in the first embodiment. For example, a photoresist film (not illustrated) having an opening in a region for forming the source electrode SE is formed. Then, a metal film is formed over the n-type contact layer (n-type AlGaN layer) CL including a portion over the photoresist film and the metal film over the photoresist is removed together with the photoresist film. Thus, the source electrode SE can be formed over the n-type contact layer (n-type AlGaN layer) CL.

Then, a heat treatment (alloying treatment) is applied, for example, to the support substrate 2S. A heat treatment about at 600° C. for about one minute is applied in a nitrogen atmosphere as the heat treatment. By the heat treatment, the source electrode SE and the channel layer (undoped GaN layer) CH to which the two-dimensional electron gas 2DEG is generated can be in ohmic contact.

Then, in the same manner as in the second embodiment, a gate insulation film GI is formed and, further, a gate electrode GE is formed. For example, an alumina film is formed as the gate insulation film GI over the electron supply layer (undoped AlGaN layer) ES including a portion over the source electrode SE by using ALD. Then, the gate insulation film GI over the source electrode SE is removed. Then, the gate electrode GE is formed over the gate insulation film GI by using, for example, a lift off method.

Then, the support substrate 2S is turned upside down such that the rear face of the support substrate 2S is situated to the upper surface, and a drain electrode DE is formed over the support substrate 2S (FIG. 40). The drain electrode DE is formed, for example, by forming a metal film over the support substrate 2S. As the metal film, a stacked film (Ti/Al) comprising, for example, a titanium (Ti) film and an aluminum (Al) film formed over the titanium film can be used. The film can be formed by using, for example, vacuum vapor deposition.

With the steps described above, the semiconductor device of this embodiment is completed substantially. In the step described above, while the gate electrode GE and the source electrode SE were formed by using the lift off method, the electrodes may also be formed by patterning the metal film.

As described above, in the semiconductor device of this embodiment, since the channel layer (undoped GaN layer) CH and the electron supply layer (undoped AlGaN layer) ES are stacked sequentially in the [000-1] direction, (1) the normally off operation and (2) the increase of the withstanding voltage can be compatibilized easily as has been described specifically for the first embodiment.

That is, the profile of the conduction band energy of the semiconductor device of this embodiment is identical with that of the first embodiment (FIG. 18). Accordingly, as has been described specifically in the first embodiment, negative charges (−σ) are generated at the interface between the electron supply layer (undoped AlGaN layer) ES and the channel layer (undoped GaN layer) CH. Accordingly, in a thermal equilibrium state at a gate voltage: Vg=0 V, the two-dimensional electron gas (channel) 2DEG just below the gate electrode (portion A-A′) is depleted to enable the normally off operation (refer to FIG. 18A). Further, in an off state at a gate voltage: Vg=threshold voltage (Vt), the potential energy of the conduction band in the gate insulation film GI decreases from the side of the substrate 2S (channel layer (undoped GaN layer) CH) to the gate electrode GE. Since the electric field strength (G/C: E is dielectric constant of the gate insulation film) does not depend on the thickness of the gate insulation film GI, the threshold voltage (Vt) increases as the thickness of the gate insulation film GI increases. As described above, in the semiconductor device of this embodiment, the normally off operation and the increase of the withstanding voltage can be compatibilized easily.

Further, in a region excluding a portion just below the gate electrode (B-B′ portion), n-type impurities in the n-type contact layer (n-type AlGaN layer) CL are ionized to form positive charges, and the two-dimensional electron gas 2DEG is generated at the interface between the electron supply layer (undoped AlGaN layer) ES and the channel layer (undoped GaN layer) CH to reduce the on resistance (refer to FIG. 18B).

Further, in this embodiment, since the opening (current constriction portion) is formed in the current block layer (p-type GaN layer) CB, carriers can be introduced efficiently to the drain. Further, according to this embodiment, the current block layer (p-type GaN layer) CB and the opening thereof (current constriction portion) can also be formed easily.

### Modification

In the embodiment illustrated in FIG. 33, the n-type impurity layer (n-type contact layer (n-type AlGaN layer) CL) was provided to a portion of the AlGaN layer (n-type contact layer (n-type AlGaN layer) CL and an electron supply layer (undoped AlGaN layer) ES), but the n-type impurity layer (n-type contact layer (n-type AlGaN layer) CL) may also be disposed to a portion of the channel layer (undoped GaN layer) CH.

For example, n-type impurities are ion implanted to the upper layer portion of the channel layer (undoped GaN layer) CH in the stack comprising the channel layer (undoped GaN layer) CH and the electron supply layer (undoped AlGaN layer) ES to form the n-type contact layer (n-type GaN layer) CL.

Further, the embodiment illustrated in FIG. 33 shows an example of a so-called MIS (metal-insulator-semiconductor) type gate electrode configuration in which the gate electrode GE is disposed by way of the gate insulation film GI over the electron supply layer (undoped AlGaN layer) ES, but a so-called Schottky type gate electrode configuration in which the gate electrode GE is disposed directly on the electron supply layer (undoped AlGaN layer) ES may also be adopted.

### Fifth Embodiment

In this embodiment, the current block layer (p-type GaN layer) CB in the third embodiment is formed by ion implantation. The semiconductor device of this embodiment is to be described below specifically with reference to the drawings.

### [Description of Structure]

Since the configuration of the semiconductor device of this embodiment is identical with that of the third embodiment (FIG. 26), detailed description therefor is to be omitted.

### [Description of Manufacturing Method]

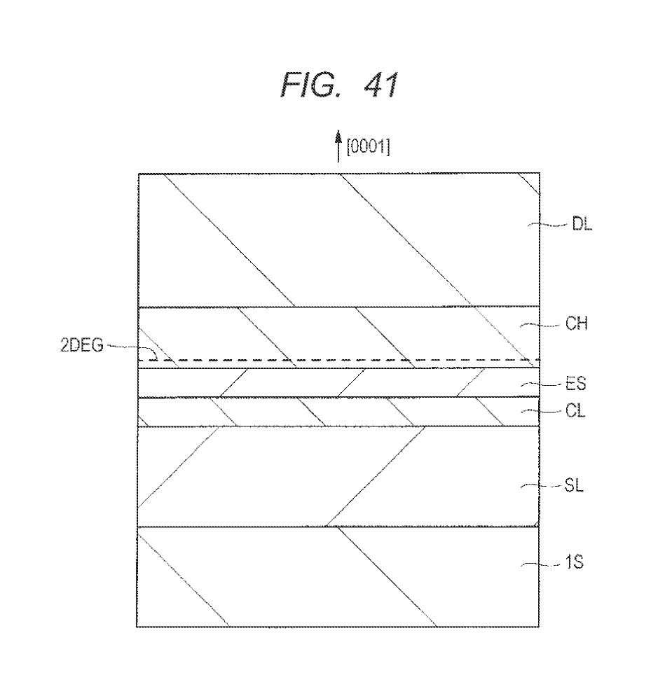

Then, a method of manufacturing a semiconductor device of this embodiment is to be described with reference to FIG. 41 to FIG. 45, and the configuration of the semiconductor device is made more definite. FIG. 41 to FIG. 45 are cross sectional views illustrating manufacturing steps of the semiconductor device of this embodiment.

As illustrated in FIG. 41, a substrate 1S comprising, for example, gallium nitride (GaN) is provided as the substrate (also referred to as a substrate for growing) 1S.

Then, a sacrificial layer SL is formed by way of a nucleation layer (not illustrated) over the substrate 1S. The sacrificial layer SL comprises, for example, a GaN layer. A sacrificial layer SL (GaN layer) of about 1 μm thickness is deposited over the substrate 1S comprising, for example, gallium nitride (GaN) by using MOCVD.

Then, an n-type contact layer CL is formed over the sacrificial layer (GaN layer) SL. For example, an n-type AlGaN layer of about 50 nm thickness is deposited by using MOCVD. The AlGaN layer has a compositional ratio shown by Al_{0.2}Ga_{0.8}N. For example, Si (silicon) is used as the n-type impurity and the concentration (impurity concentration) thereof is, for example, about 1×10¹⁹/cm³. Then, an electron supply layer ES is formed over the n-type contact layer (n-type AlGaN layer) CL. For example, an undoped AlGaN layer of about 20 nm thickness is deposited by using MOCVD. The AlGaN layer has a compositional ratio shown by Al_{0.2}Ga_{0.8}N. Then, a channel layer CH is formed over the electron supply layer (undoped AlGaN layer) ES. An undoped GaN layer of about 0.1 μm thickness is deposited by using, for example, MOCVD. Then, an n-type drift layer (n-type GaN layer) DL is formed over the channel layer CH (undoped GaN layer). For example, an n-type drift layer (n-type GaN layer) DL of about 10 μm thickness is grown over the channel layer CH (undoped GaN layer) by using MOCVD. For example, Si (silicon) is used as the n-type impurity and the concentration (impurity concentration) thereof is, for example, about 5×10¹⁶/cm³.

The grown film formed by using MOCVD described above is referred to as an epitaxial layer (epitaxial film). The stack comprising the sacrificial layer (GaN layer) SL, the n-type contact layer (n-type AlGaN layer) CL, the electron supply layer (undoped AlGaN layer) ES, and the channel layer (undoped GaN layer) CH is formed in a growth mode over the Ga plane parallel with the [0001] crystal axis direction. In other words, respective layers are grown successively over the Ga plane parallel with the [0001] crystal axis direction.

Specifically, GaN is grown over the Ga plane ((0001) plane) of the substrate 1S comprising gallium nitride (GaN) in the [0001] direction to form the sacrificial layer (GaN layer) SL. Then, n-type AlGaN is grown over the Ga plane ((0001) plane) of the sacrificial layer (GaN layer) SL in the [0001] direction to form an n-type contact layer (n-type AlGaN layer) CL. Then, undoped AlGaN is grown over the Ga plane (0001 plane) of the n-type contact layer (n-type contact layer) CL in the [0001] direction to form the electron supply layer (undoped AlGaN layer) ES. Then, undoped GaN is grown over the Ga plane ((0001) plane) of the electron supply layer (undoped AlGaN layer) ES in the [0001] direction to form a channel layer (undoped GaN layer) CH. Then, n-type GaN is grown over the Ga plane ((0001) plane) of the channel layer (undoped GaN layer) CH in the [0001] direction to form an n-type drift layer (n-type GaN layer) DL.

A two-dimensional electron gas (two-dimensional electron gas layer) 2DEG is generated (formed) near the interface between the electron supply layer (undoped AlGaN layer) ES and the channel layer (undoped GaN layer) CH. The surface that generates the two-dimensional electron gas, that is, the junction plane (interface) between the electron supply layer (undoped AlGaN layer) ES and the channel layer (undoped GaN layer) CH is the Ga plane ((0001) plane) and the direction from the junction plane (plane that generates the two-dimensional gas 2DEG) to the channel layer (undoped GaN layer) CH is the [0001] direction.

As described above, by forming each of the layers of the stack (n-type contact layer (n-type AlGaN layer) CL, electron supply layer (undoped AlGaN layer) ES, channel layer (undoped GaN layer) CH, and n-type drift layer (n-type GaN layer) DL) in the growth mode over the Ga plane parallel with the [0001] crystal axis direction, a stack comprising more planar epitaxial layers with less unevenness can be obtained.

While the lattice constant is different between AlGaN and GaN, a stack of good crystal quality with less occurrence of dislocation can be obtained by setting the total film thickness of AlGaN to a critical film thickness or less.

As the substrate 1S, substrates other than the substrate comprising gallium nitride (GaN) may also be used. When a substrate comprising gallium nitride (GaN) is used, a stack of good crystal quality with less occurrence of dislocation can be grown. Crystal defects such as the dislocation described above cause leak current. Accordingly, leak current can be decreased by suppressing the crystal defects and the off withstanding voltage of a transistor can be improved.

As the nucleation layer (not illustrated) over the substrate 1S, a super lattice layer (AlN/GaN film) formed by repeatingly stacking a stacked film comprising a gallium nitride (GaN) layer and an aluminum nitride (AlN) layer can be used.

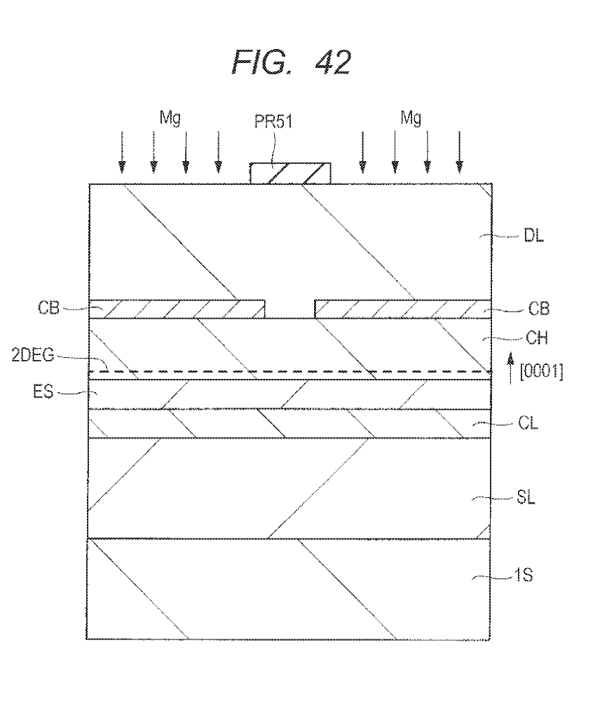

Then, as illustrated in FIG. 42, a p-type current block layer (p-type GaN layer) CB is formed by ion implantation. First, a photoresist film PR51 is formed to a region intended to form a gate electrode GE over the n-type drift layer (n-type GaN layer) DL. Then, p-type impurities are ion implanted to the bottom of the n-type drift layer (n-type GaN layer) DL by using the photoresist film PR51 as a mask. Thus, a p-type current block layer (p-type GaN layer) CB is formed to the bottom of the n-type drift layer (n-type GaN layer) DL on both sides of a region intended to form the gate electrode GE, that is, near the interface between the n-type drift layer (n-type GaN layer) DL and the channel layer (undoped GaN layer) CH. For example, Mg (magnesium) is used as the p-type impurity and the concentration (impurity concentration) thereof is, for example, about 1×10¹⁹/cm³. The thickness of the p-type current block layer (p-type GaN layer) CB is, for example, about 0.5 μm. Subsequently, the photoresist film PR51 is removed. Then, a heat treatment (annealing) is applied, for example, in a nitrogen atmosphere to activate the p-type impurities (Mg in this embodiment) in the p-type current block layer (p-type GaN layer) CB. By the heat treatment, a hole concentration in the n-type contact layer (n-type AlGaN layer) CL is, for example, about 2×10¹⁸/cm³.

Upon forming the p-type current block layer (p-type GaN layer) CB, when the p-type current block layer (p-type GaN layer) CB of Comparative Example 2 is formed by ion implantation, it is necessary to implant impurity ions from the electron supply layer ES by way of the interface (two-dimensional electron gas 2DEG) between the electron supply layer (undoped AlGaN layer) ES and the channel layer (undoped GaN layer) CH. Accordingly, there may be a possibility that the layers may be damaged by implantation of the impurity ions thereby lowering the carrier mobility and carrier concentration at the interface (two-dimensional electron gas 2DEG).

On the contrary, according to this embodiment, since the impurity ions can be implanted from the n-type drift layer (n-type GaN layer) DL, the interface between the electron supply layer (undoped AlGaN layer) ES and the channel layer (undoped GaN layer) CH (two-dimensional electron gas 2DEG) is less damaged by implantation of the impurity ions. Accordingly, the carrier mobility and the carrier concentration can be improved at the interface (two-dimensional electron gas 2DEG).

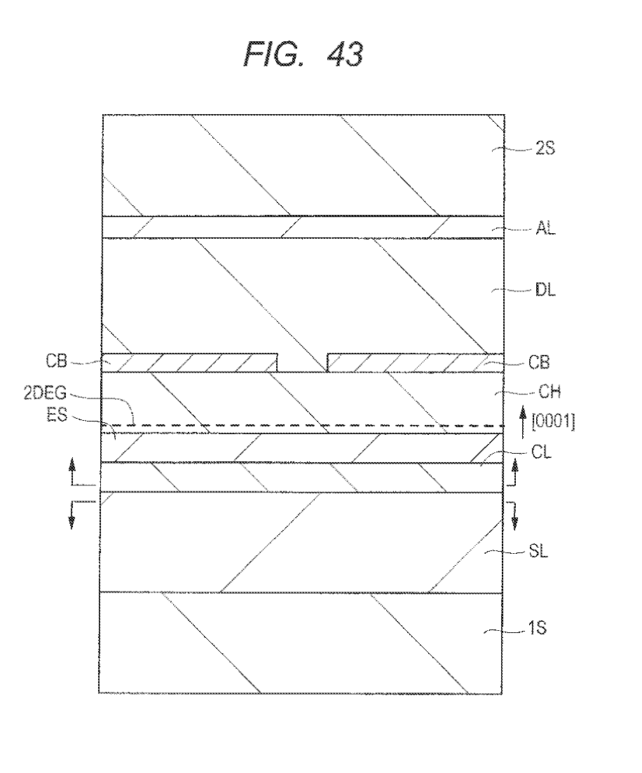

Then, as illustrated in FIG. 43, a bonding layer AL is formed over the (0001) plane of the n-type drift layer (n-type GaN layer) DL and a support substrate 2S is mounted thereover. As the bonding layer AL, a solder layer comprising, for example, an alloy of Au (gold) and tin (Sn) can be used. Further, a metal film (metallized film) may also be provided above and below the solder layer. For example, a stacked film (Ti/Al) comprising a titanium (Ti) film and an aluminum (Al) film formed over the titanium film is formed as a metal film over the (0001) plane of the n-type drift layer (n-type GaN layer) DL, and a solder layer is formed thereover. Alternatively, a stacked film (Ti/Pt/Au) comprising a titanium (Ti) film, a platinum (Pt) film formed over the titanium film, and a gold (Au) film formed on the platinum film is formed as the metal film over the support substrate 2S. As the support substrate 2S, a substrate comprising silicon (Si) can be used.

Then, the solder layer as the bonding layer AL and the metal film of the support substrate 2S are opposed and the n-type drift layer (n-type GaN layer) DL and the support substrate 2S are fused by way of the solder layer (bonding layer AL).

Then, the sacrificial layer (GaN layer) SL and the substrate 1S are peeled from the interface between the sacrificial layer (GaN layer) SL and the n-type contact layer (n-type AlGaN layer) CL. As the peeling method, a laser lift off method can be used in the same manner as in the first embodiment.

Thus, a stacked structure in which the n-type contact layer (n-type AlGaN layer) CL, the electron supply layer (undoped AlGaN layer) ES, the channel layer (undoped GaN layer) CH, the current block layer (p-type GaN layer) CB, and the n-type drift layer (n-type GaN layer) DL are stacked is formed and, further, the bonding layer AL and the support substrate 2S are stacked thereover is formed.

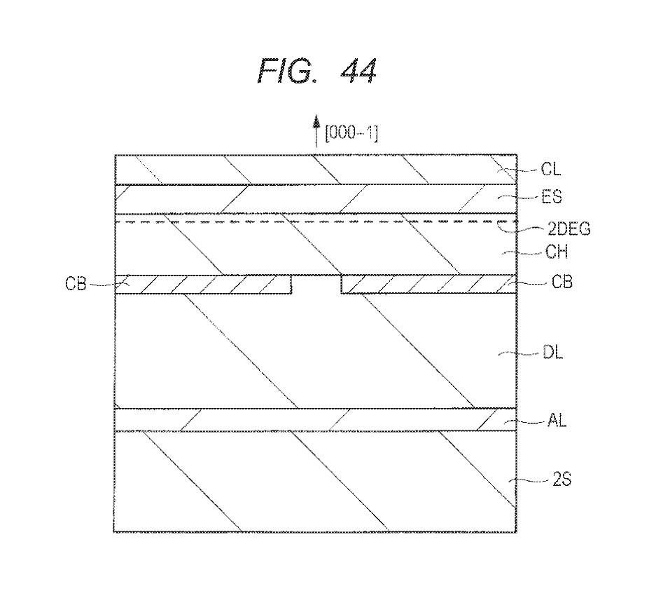

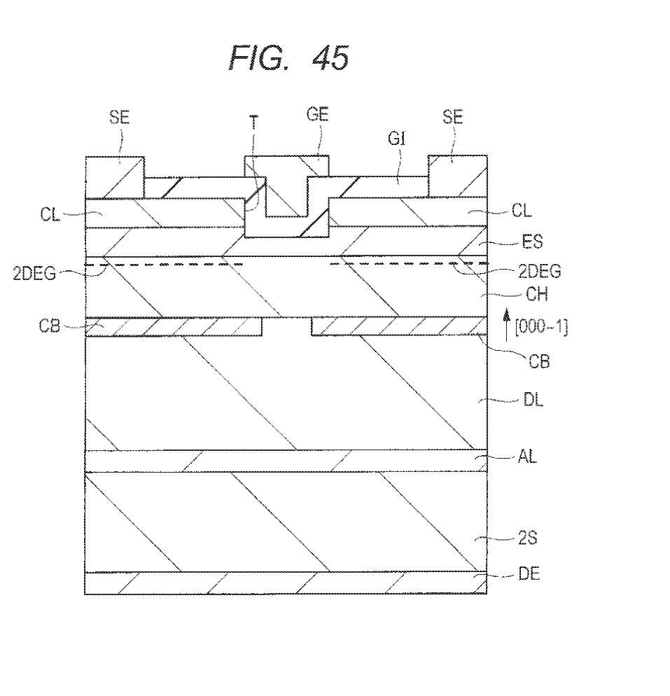

Then, as illustrated in FIG. 44, the stacked structure is turned upside down such that the n-type contact layer (n-type AlGaN layer) CL of the stacked structure is situated to the upper surface. Thus, the stack is disposed by way of the bonding layer AL over the support substrate 2S. As has been described above, the junction plane between the electron supply layer (undoped AlGaN layer) ES and the channel layer (undoped GaN layer) CH is the Ga plane ((0001) plane). Then, the direction from the junction plane (plane that generates two-dimensional electron gas 2DEG) to the electron supply layer (undoped AlGaN layer) ES is the [000-1] direction.

Then, as illustrated in FIG. 45, a source electrode SE is formed over the n-type contact layer (n-type AlGaN layer) CL. The source electrode SE can be formed by using a lift off method in the same manner as in the first embodiment. For example, a photoresist film (not illustrated) having an opening in a region for forming the source electrode SE is formed. Then, a metal film is formed over the n-type contact layer (n-type AlGaN layer) CL including a portion over the photoresist film, and the metal film over the photoresist is removed together with the photoresist film. Thus, the source electrode SE can be formed over the n-type contact layer (n-type AlGaN layer) CL.

Then, a heat treatment (alloying treatment) is applied to the support substrate 2S. A heat treatment about at 600° C. for one minute is applied, for example, in a nitrogen atmosphere as the heat treatment. By the heat treatment, the source electrode SE and the channel layer (undoped GaN layer) CH to which the two-dimensional electron gas 2DEG is generated can be in ohmic contact.

Then, in the same manner as in the first embodiment, after forming a trench T, a gate insulation film GI is formed and, further, a gate electrode GE is formed. That is, the n-type contact layer (n-type AlGaN layer) CL is removed by using, for example, dry etching to form the trench T that passes through the n-type contact layer (n-type AlGaN layer) CL and allows the electron supply layer (undoped AlGaN layer) ES to be exposed. Then, as the gate insulation film GI, an alumina film is formed, for example, over the electron supply layer (undoped AlGaN layer) ES including a portion over the source electrode SE by using ALD. Then, the gate insulation film GI over the source electrode SE is removed. Then, a gate electrode GE is formed over the gate insulation film GI in the inside of the trench T by using, for example, a lift off method.

Then, the support substrate 2S is turned upside down such that the rear face of the support substrate 2S is situated to the upper surface and a drain electrode DE is formed. For example, the drain electrode DE is formed by forming a metal film over the support substrate 2S. As the metal film, a stacked film (Ti/Al) comprising, for example, a titanium (Ti) film and an aluminum (Al) film formed over the titanium film can be used. The film can be formed by using, for example, vacuum vapor deposition.

With the steps described above, the semiconductor device of this embodiment is completed substantially. While the gate electrode GE and the source electrode SE were formed in the step described above by using the lift off method, the electrodes may also be formed by patterning the metal film.

As described above, in the semiconductor device of this embodiment, since the channel layer (undoped GaN layer) CH and the electron supply layer (undoped AlGaN layer) ES are stacked sequentially in the [000-1] direction, (1) the normally off operation and (2) the increase of the withstanding voltage can be compatibilized easily as has been described specifically in the first embodiment.

That is, the profile of the conduction band energy of the semiconductor device of this embodiment is identical with that of the first embodiment (FIG. 18). Accordingly, as has been described specifically in the first embodiment, negative charges (−σ) are generated at the interface between the electron supply layer (undoped AlGaN layer) ES and the channel layer (undoped GaN layer) CH. Accordingly, in a thermal equilibrium state at a gate voltage: Vg=0 V, the two-dimensional electron gas (channel) 2DEG just below the gate electrode (portion A-A′) is depleted to enable the normally off operation (refer to FIG. 18A). Further, in an off state at a gate voltage: Vg=threshold voltage (Vt), the potential energy of the conduction band in the gate insulation film GI decreases from the side of the substrate 2S (channel layer (undoped GaN layer) CH to the gate electrode GE. Since the electric field strength (σ/∈: ∈ is dielectric constant of the gate insulation film) does not depend on the thickness of the gate insulation film GI, the threshold voltage (Vt) increases as the thickness of the gate insulation film GI increases. As described above, in the semiconductor device of this embodiment, the normally off operation and the increase of the withstanding voltage can be compatibilized easily.

Further, in a region excluding a portion just below the gate electrode (B-B′ portion), n-type impurities in the n-type contact layer (n-type AlGaN layer) CL are ionized to form positive charges, and a two-dimensional electron gas 2DEG is generated at the interface between the electron supply layer (undoped AlGaN layer) ES and the channel layer (undoped GaN layer) CH to reduce the on resistance (refer to FIG. 18B).

Further, in this embodiment, since the opening (current constriction portion) is formed in the current block layer (p-type GaN layer) CB, carriers can be introduced efficiently to the drain. Further, according to this embodiment, the current block layer (p-type GaN layer) CB and the opening thereof (current constriction portion) can also be formed easily.

### Modification

In the embodiment illustrated in FIG. 45, the n-type impurity layer (n-type contact layer (n-type AlGaN layer) CL) was disposed to a portion of the AlGaN layer (n-type contact layer (n-type AlGaN layer) CL and the electron supply layer (undoped AlGaN layer) ES), but the n-type impurity layer (n-type contact layer (n-type AlGaN layer) CL) may also be disposed to a portion of the channel layer (undoped GaN layer) CH.

For example, after stacking the channel layer (undoped GaN layer) CH, the n-type contact layer (n-type GaN layer) CL, and the electron supply layer (undoped AlGaN layer) ES, the electron supply layer (undoped AlGaN layer) ES and the n-type contact layer (n-type GaN layer) CL may be removed to form the trench T.

Further, the embodiment illustrated in FIG. 45 shows an example of a so-called MIS (metal-insulator-semiconductor) type gate electrode configuration in which the gate electrode GE is disposed by way of the gate insulation film GI over the electron supply layer (undoped AlGaN layer) ES, but a so-called Schottky type gate electrode configuration in which the gate electrode GE is disposed directly on the electron supply layer (undoped AlGaN layer) ES may also be adopted.

### Sixth Embodiment

In this embodiment, the current block layer (p-type GaN layer) CB in the fourth embodiment is formed by ion implantation. The semiconductor device of this embodiment is to be described specifically with reference to the drawings.

### [Description of Structure]

Since the configuration of the semiconductor device of this embodiment is identical with that of the fourth embodiment (FIG. 33), detailed description therefor is to be omitted.

### [Description of Manufacturing Method]

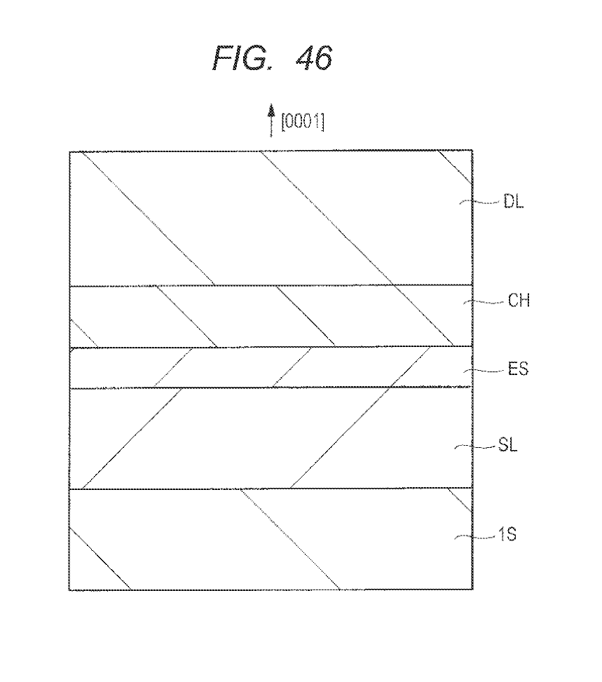

Then, a method of manufacturing the semiconductor device of this embodiment is to be described with reference to FIG. 46 to FIG. 50, and the configuration of the semiconductor device is made more definite. FIG. 46 to FIG. 50 are cross sectional views illustrating manufacturing steps of the semiconductor device of this embodiment.

As illustrated in FIG. 46, a substrate 1S comprising, for example, gallium nitride (GaN) is provided as the substrate (also referred to as a growth substrate) 1S.

Then, a sacrificial layer SL is formed by way of a nucleation layer (not illustrated) over the substrate 1S. The sacrificial layer SL comprises, for example, a GaN layer. For example, a sacrificial layer (GaN layer) SL of about 1 μm thickness is deposited over the substrate 1S comprising gallium nitride (GaN) by using MOCVD.

Then, an electron supply layer ES is formed over the sacrificial layer (GaN layer) SL. For example, an undoped AlGaN layer of about 50 nm thickness is deposited by using MOCVD. The AlGaN layer has a compositional ratio shown by Al_{0.2}Ga_{0.8}N. Then, a channel layer CH is formed over the electron supply layer (undoped AlGaN layer) ES. For example, an undoped GaN layer of about 0.1 thickness is deposited by using MOCVD. Then, an n-type drift layer (n-type GaN layer) DL is formed over the channel layer CH (undoped GaN layer). For example, an n-type drift layer (n-type GaN layer) DL of about 10 μm thickness is grown over the channel layer CH (undoped GaN layer) by using MOCVD. For example, Si (silicon) is used as the n-type impurity and the concentration (impurity concentration) thereof is, for example, about 5×10¹⁶/cm³.

The grown film formed by using MOCVD described above is referred to as an epitaxial layer (epitaxial film). The stack comprising the sacrificial layer (GaN layer) SL, the electron supply layer (undoped AlGaN layer) ES, the channel layer (undoped GaN layer) CH, and the n-type drift layer (n-type GaN layer) DL is formed in a growth mode over the Ga plane parallel with the [0001] crystal axis direction. In other words, respective layers are grown successively over the Ga plane parallel with the [0001] crystal axis direction.

Specifically, GaN is grown over the Ga plane ((0001) plane) of the substrate 1S comprising gallium nitride (GaN) in the [0001] direction to form a sacrificial layer (GaN layer) SL. Then, undoped AlGaN is grown over the Ga plane ((0001) plane) of the sacrificial layer (GaN layer) SL in the [0001] direction to form an electron supply layer (undoped AlGaN layer) ES. Then, undoped GaN is grown over the Ga plane ((0001) plane) of the electron supply layer (undoped AlGaN layer) ES in the [0001] direction to form a channel layer (undoped GaN layer) CH. Then, n-type GaN is grown over the Ga plane ((0001) plane) of the channel layer (undoped GaN layer) CH in the [0001] direction to form an n-type drift layer (n-type GaN layer) DL.

An interface (junction plane) between the electron supply layer (undoped AlGaN layer) ES and the channel layer (undoped GaN layer) CH is the Ga plane ((0001) plane) and the direction from the interface (junction plane) to the channel layer (undoped GaN layer) CH is the [0001] direction.

As described above, by forming each of the layers of the stack (sacrificial layer (AlGaN layer) SL, electron supply layer (undoped AlGaN layer) ES, channel layer (undoped GaN layer) CH, and n-type drift layer (n-type GaN layer) DL) in a growth mode over the Ga plane parallel with the [0001] crystal axis direction, a stack comprising more planar epitaxial layers with less unevenness can be obtained.

While the lattice constant is different between AlGaN and GaN, a stack of good crystal quality with less occurrence of dislocation can be obtained by setting the total film thickness of AlGaN to a critical film thickness or less.

As the substrate 1S, substrates other than the substrate comprising gallium nitride (GaN) may also be used. When the substrate comprising gallium nitride (GaN) is used, a stack of good crystal quality with less occurrence of dislocation can be grown. Crystal defects such as the dislocation described above cause leak current. Accordingly, leak current can be decreased by suppressing the crystal defects, and the off withstanding voltage of a transistor can be improved.

As the nucleation layer (not illustrated) over the substrate 1S, a super lattice layer formed by repeatingly stacking a stacked film (AlN/GaN film) comprising a gallium nitride (GaN) layer and an aluminum nitride (AlN) layer can be used.

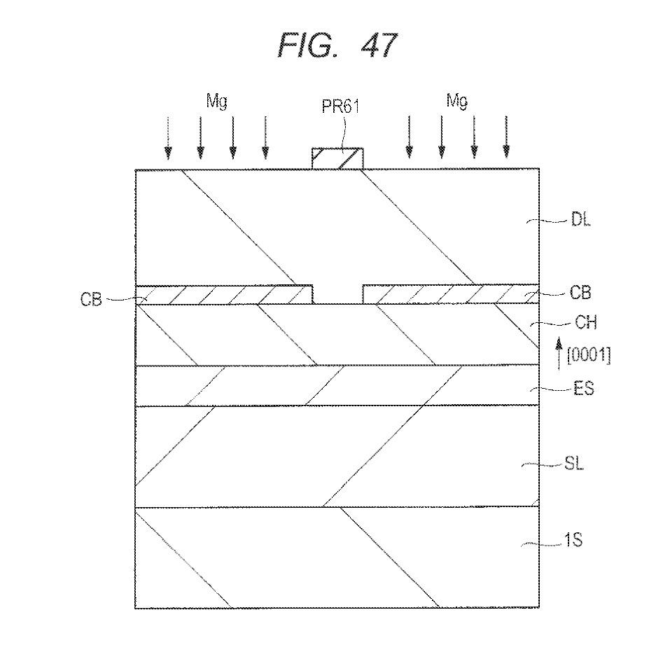

Then, as illustrated in FIG. 47, a p-type current block layer (p-type GaN layer) CB is formed by ion implantation. First, a photoresist film PR61 is formed to a region intended to form a gate electrode GE over the n-type drift layer (n-type GaN layer) DL. Then, p-type impurities are ion implanted to the bottom of the n-type drift layer (n-type GaN layer) DL by using the photoresist film PR61 as a mask. Thus, a p-type current block layer (p-type GaN layer) CB is formed to the bottom of the n-type drift layer (n-type GaN layer) DL, that is, near the interface between the n-type drift layer (n-type GaN layer) DL and the channel layer (undoped GaN layer) CH on both sides of a region intended to form the gate electrode GE. For example, Mg (magnesium) is used as the p-type impurity and the concentration (impurity concentration) thereof is, for example, about 1×10¹⁹/cm³. The thickness of the p-type current block layer (p-type GaN layer) CB is, for example, about 0.5 μm. Subsequently, the photoresist film PR61 is removed. Then, a heat treatment (annealing) is applied, for example, in a nitrogen atmosphere to activate the p-type impurity (Mg in this embodiment) in the p-type current block layer (p-type GaN layer) CB. By the heat treatment, a hole concentration in the p-type current block layer (p-type GaN layer) CB is, for example, about 2×10¹⁸/cm³.

Upon forming the p-type current block layer (p-type GaN layer) CB, when the p-type current block layer (p-type GaN layer) CB of Comparative Example 2 (FIG. 16) is formed by the ion implantation, it is necessary to implant impurity ions from the electron supply layer ES by way of the interface (two-dimensional electron gas 2DEG) between the electron supply layer (undoped AlGaN layer) ES and the channel layer (undoped GaN layer) CH. Accordingly, there may be a possibility that the layers may be damaged by implantation of impurity ions thereby lowering the carrier mobility and carrier concentration at the interface (two-dimensional electron gas 2DEG).

On the contrary, according to this embodiment, since the impurity ions can be implanted from the n-type drift layer (n-type GaN layer) DL, the interface (two-dimensional electron gas 2DEG) between the electron supply layer (undoped AlGaN layer) ES and the channel layer (undoped GaN layer) CH is less damaged by the implantation of the impurity ions. Accordingly, carrier mobility and carrier concentration at the interface (two-dimensional electron gas 2DEG) can be improved.

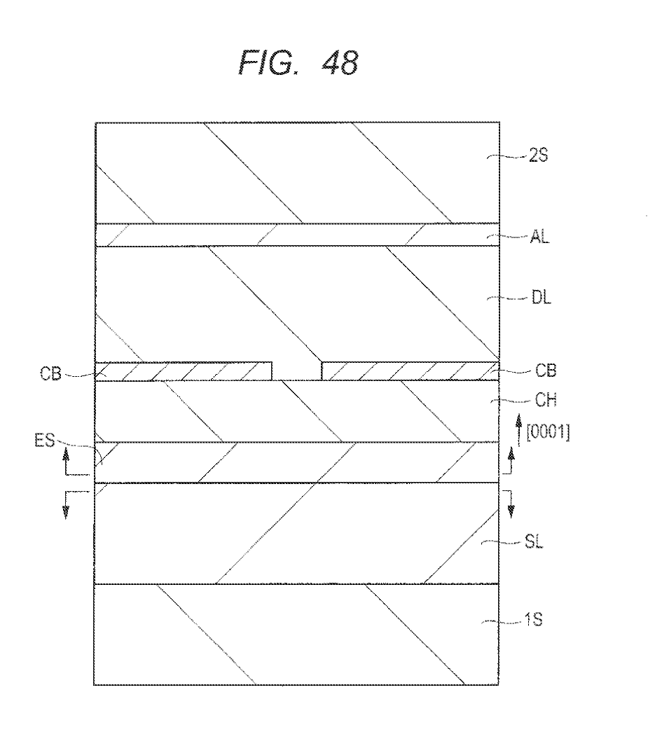

Then, as illustrated in FIG. 48, a bonding layer AL is formed over the (0001) plane of the n-type drift layer (n-type GaN layer) DL and a support substrate 2S is mounted thereover. For example, an Ag (silver) paste can be used as the bonding layer AL. Further, a metal film (metallized film) may also be provided above and below the Ag (silver) paste. For example, a stacked film (Ti/Al) comprising a titanium (Ti) film and an aluminum (Al) film formed over the titanium film is formed as a metal film over the (0001) plane of the n-type drift layer (n-type GaN layer) DL, and the Ag (silver) paste is formed thereover. Further, a stacked film (Ti/Pt/Au) comprising a titanium (Ti) film, a platinum (Pt) film formed over the titanium film, and a gold (Au) film formed on the platinum film is formed as the metal film over the support substrate 2S. As the support substrate 2S, a substrate comprising silicon (Si) can be used.

Then, the Ag (silver) paste as the bonding layer AL and the metal film of the support substrate 2S are opposed, and the n-type drift layer (n-type GaN layer) DL and the support substrate 2S are fused by way of the Ag (silver) paste (bonding layer AL).

Then, the sacrificial layer (GaN layer) SL and the substrate 1S are peeled from the interface between the sacrificial layer (GaN layer) SL and the electron supply layer (undoped AlGaN layer) ES. As the peeling method, a laser lift off method can be used in the same manner as in the first embodiment.

Thus, a stacked structure in which the electron supply layer (undoped AlGaN layer) ES, the channel layer (undoped GaN layer) CH, the current block layer (p-type GaN layer) CB, and the n-type drift layer (n-type GaN layer) DL are stacked and, further, the bonding layer AL and the support substrate 2S are stacked thereover is formed.

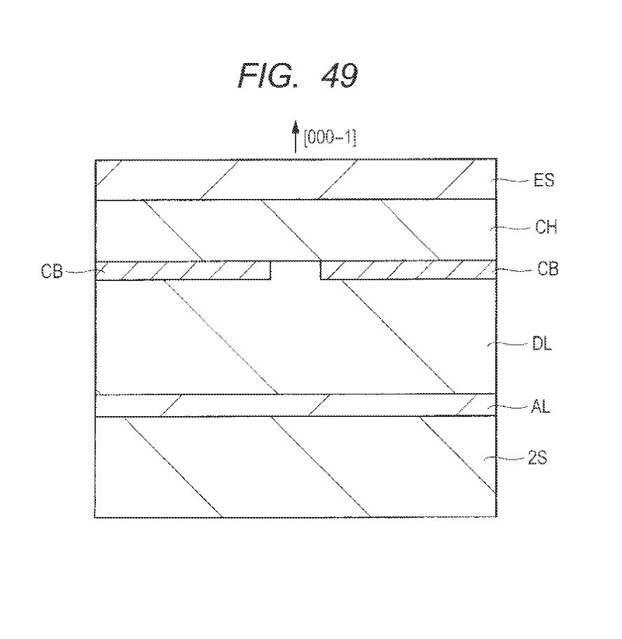

Then, as illustrated in FIG. 49, the stacked structure is turned upside down such that the electron supply layer (undoped AlGaN layer) ES of the stacked structure is situated to the upper surface. Thus, the stack is disposed by way of the bonding layer AL over the support substrate 2S. As has been described above, the junction plane between the electron supply layer (undoped AlGaN layer) ES and the channel layer (undoped GaN layer) CH is the Ga plane ((0001) plane). The direction from the junction plane to the electron supply layer (undoped AlGaN layer) ES is the [000-1] direction.

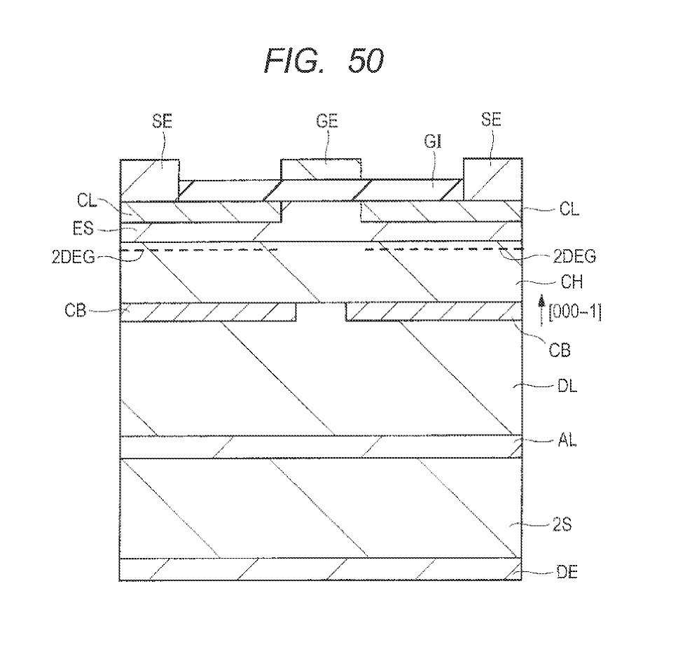

Then, as illustrated in FIG. 50, an n-type contact layer (n-type AlGaN layer) CL is formed by ion implantation. First, a photoresist film (not illustrated) is formed over the region intended to form a gate electrode GE of an electron supply layer (undoped AlGaN layer) ES. Then, n-type impurities are ion implanted into an upper layer portion of the electron supply layer (undoped AlGaN layer) ES by using the photoresist film as a mask. Thus, an n-type contact layer (n-type AlGaN layer) CL is formed to the upper layer portion of the electron supply layer (undoped AlGaN layer) ES on both sides of the region intended to form the gate electrode GE. For example, Si (silicon) is used as the n-type impurity, and the concentration (impurity concentration) thereof is, for example, about 1×10¹⁹/cm³. The thickness of the n-type contact layer (n-type AlGaN layer) CL is, for example, about 30 nm. Then, the photoresist film is removed. Then, a heat treatment (annealing) is applied, for example, in a nitrogen atmosphere to activate the n-type impurity (Si in this embodiment) in the n-type contact layer (n-type AlGaN layer) CL. By the heat treatment, the electron concentration in the n-type contact layer (n-type AlGaN layer) CL is, for example, about 2×10¹⁹/cm³.

Then, a source electrode SE is formed over the n-type contact layer (n-type AlGaN layer) CL on both sides of a region intended to form the gate electrode GE. The source electrode SE can be formed by using, for example, a lift off method in the same manner as in the first embodiment. Then, a heat treatment (alloying treatment) is applied to the support substrate 2S in the same manner as in the first embodiment. By the heat treatment, the source electrode SE and the channel layer (undoped GaN layer) CH to which the two-dimensional electron gas 2DEG is formed (undoped GaN layer) CH can be in ohmic contact. That is, the source electrodes SE are in a state connected electrically to the two-dimensional electron gas 2DEG respectively.

Then, after forming a gate insulation film GI, a gate electrode GE is formed. First, the gate insulation film GI is formed in the same manner as in the second embodiment. For example, an alumina film is formed as the gate insulation film GI over the source electrode SE, the electron supply layer (undoped AlGaN layer) ES, and the n-type contact layer (n-type AlGaN layer) CL by using atomic layer deposition. Then, the gate insulation film GI over the source electrode SE is removed. The gate insulation film GI may be removed also upon forming contact holes over the source electrode SE.

Then, a gate electrode GE is formed over the gate insulation film GI. The gate electrode GE can be formed by using, for example, a lift off method in the same manner as in the second embodiment.

Then, the support substrate 2S is turned upside down such that the back surface of the support substrate 2S is situated to the upper surface and a drain electrode DE is formed over the support substrate 2S. For example, the drain electrode DE is formed by forming a metal film on the support substrate 2S. For example, a stacked film (Ti/Al) comprising a titanium (Ti) film and an aluminum (Al) film formed over the titanium film can be used as the metal film. The film can be formed by using, for example, vacuum vapor deposition.

With the steps described above, the semiconductor device of this embodiment is completed substantially. While the gate electrode GE and the source electrode SE were formed in the step described above by using the lift off method, the electrodes may also be formed by patterning the metal film.

As described above, in the semiconductor device of this embodiment, since the channel layer (undoped GaN layer) CH and the electron supply layer (undoped AlGaN layer) ES are stacked sequentially in the [000-1] direction, (1) the normally off operation and (2) the increase of the withstanding voltage can be compatibilized easily as has been described specifically in the first embodiment.

That is, the profile of the conduction band energy of the semiconductor device of this embodiment is identical with that of the first embodiment (FIG. 18). Accordingly, as has been described specifically in the first embodiment, negative charges (−σ) are generated at the interface between the electron supply layer (undoped AlGaN layer) ES and the channel layer (undoped GaN layer) CH. Accordingly, in a thermal equilibrium state at a gate voltage: Vg=0 V, the two-dimensional electron gas (channel) 2DEG just below the gate electrode (portion A-A′) is depleted to enable the normally off operation (refer to FIG. 18A). Further, in an off state at a gate voltage: Vg=threshold voltage (Vt), the potential energy of the conduction band in the gate insulation film GI decreases from the side of the substrate 2S (channel layer (undoped GaN layer) CH to the gate electrode GE. Since the electric field strength (σ/∈: ∈ is a dielectric constant of the gate insulation film) does not depend on the thickness of the gate insulation film GI, the threshold voltage (Vt) increases as the thickness of the gate insulation film GI increases. As described above, in the semiconductor device of this embodiment, the normally off operation and the increase of the withstanding voltage can be compatibilized easily.

Further, in a region excluding a portion just below the gate electrode (B-B′ portion), n-type impurities in the n-type contact layer (n-type AlGaN layer) CL are ionized to form positive charges, and a two-dimensional electron gas 2DEG is generated at the interface between the electron supply layer (undoped AlGaN layer) ES and the channel layer (undoped GaN layer) CH to reduce the on resistance (refer to FIG. 18B).

Further, in this embodiment, since the step of forming the trench T is not necessary, the threshold voltage (Vt) can be controlled more easily than in the first embodiment, etc.

Further, in this embodiment, since the opening (current constriction portion) is formed in the current block layer (p-type GaN layer) CB, carriers can be introduced efficiently to the drain. Further, according to this embodiment, the current block layer (p-type GaN layer) CB and the opening thereof (current constriction portion) can also be formed easily.

Further, in this embodiment, it is not necessary to use filling re-growth explained in the fourth embodiment, etc. and the semiconductor device can be manufactured by a simpler step.

### Modification

In the embodiment illustrated in FIG. 50, the n-type impurity layer (n-type contact layer (n-type AlGaN layer) CL) was disposed to a portion of the AlGaN layer (n-type contact layer (n-type AlGaN layer) CL and the electron supply layer (undoped AlGaN layer) ES), but the n-type impurity layer (n-type contact layer (n-type AlGaN layer) CL) may also be disposed to a portion of the channel layer (undoped GaN layer) CH.

For example, in the stack of the channel layer (undoped GaN layer) CH and the electron supply layer (undoped AlGaN layer) ES, the n-type impurities are ion implanted to the upper layer portion of the channel layer (undoped GaN layer) CH, to form an n-type contact layer (n-type GaN layer) CL.

Further, the embodiment illustrated in FIG. 50 shows an example of a so-called MIS (metal-insulator-semiconductor) type gate electrode configuration in which the gate electrode GE is disposed by way of the gate insulation film GI over the electron supply layer (undoped AlGaN layer) ES, but a so-called Schottky type gate electrode configuration in which the gate electrode GE is disposed directly on the electron supply layer (undoped AlGaN layer) ES may also be adopted.

### Description of Common Modification

In this section, other modifications in common with the first to the sixth embodiments are to be described.

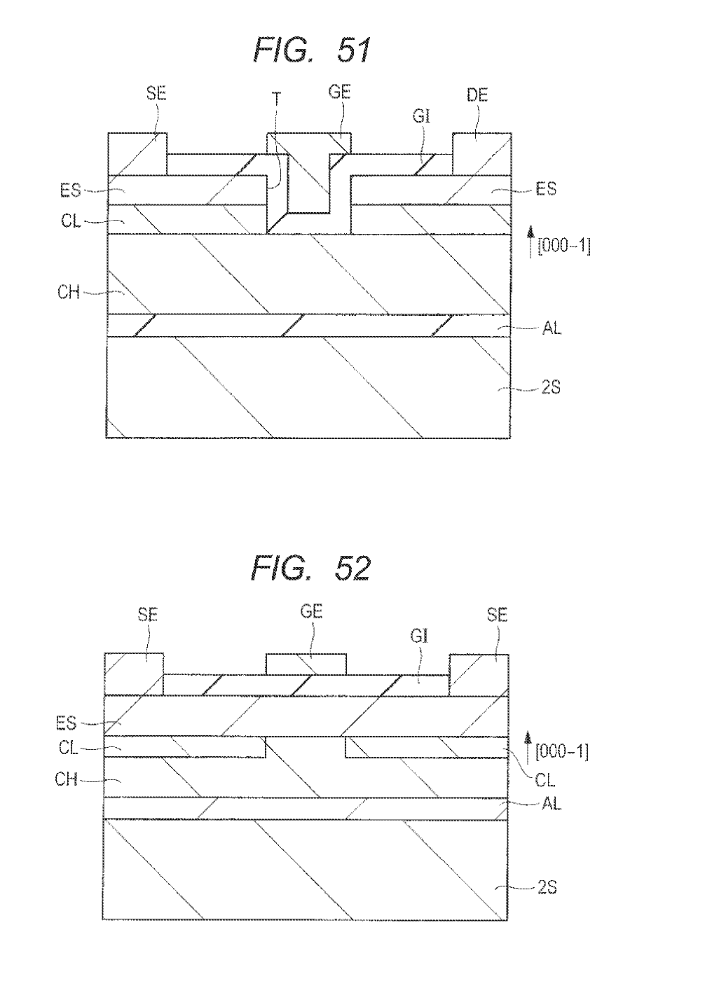

As has been described above, in the first to the sixth embodiments, while the n-type impurity layer (n-type contact layer (n-type AlGaN layer) CL) is disposed to a portion of the AlGaN layer (n-contact layer (n-type AlGaN layer) CL) and the electron supply layer (undoped AlGaN layer) ES), the n-type impurity layer (n-type contact layer (n-type AlGaN layer) CL) may also be disposed to a portion of the channel layer (undoped GaN layer) CH. In other words, either the n-type impurity layer (n-type contact layer (n-type AlGaN layer) CL) may be disposed to a portion of the electron supply layer (undoped AlGaN layer) ES, or the n-type impurity layer (n-type contact layer (n-type AlGaN layer) CL) may also be disposed to a portion of the channel layer (undoped GaN layer) CH. FIG. 51 is a cross sectional view illustrating a configuration example of a lateral semiconductor device in which the n-type impurity layer is disposed to a portion of a channel layer. FIG. 52 is a cross sectional view illustrating a configuration example of a vertical semiconductor device in which the n-type impurity layer is disposed to a portion of the channel layer. Portions in common with the first to the sixth embodiments carry the same reference numerals, for which duplicate description is to be omitted.

For example, as illustrated in FIG. 51, a trench T may be formed by stacking a channel layer (undoped GaN layer) CH, an n-type contact layer (n-type GaN layer) CL, and an electron supply layer (undoped AlGaN layer) ES, and then removing the electron supply layer (undoped AlGaN layer) ES and the n-type contact layer (n-type GaN layer) CL.

Further, as illustrated in FIG. 52, in a stack comprising a channel layer (undoped GaN layer) CH and an electron supply layer (undoped AlGaN layer) ES, an n-type contact layer (n-type GaN layer) CL may be formed by ion implanting n-type impurities into an upper layer portion of a channel layer (undoped GaN layer) CH.

As described above, the n-type contact layer CL may be formed in the electron supply layer ES as a portion thereof, or may be formed in the channel layer CH as a portion thereof.

In the first to the sixth embodiments described above, while a substrate comprising silicon (Si) is used as the support substrate 2S, a substrate comprising silicon carbide (SiC), a sapphire substrate, or a substrate comprising silicon (Si), etc. can also be used.

Further, in the first to the sixth embodiments, while the super lattice layer formed by repeatingly stacking AlN/GaN films was used as the nucleation layer, a monolayer film, for example, an AlN film, an AlGaN film, or a GaN film may also be used.

Further, in the first to the sixth embodiments, while the GaN (GaN layer) was used as the channel layer CH, group III nitride semiconductors such as AlGaN, AlInN, AlGaInN, InGaN, and indium nitride (InN) may also be used.

Further, in the first to the sixth embodiments, while AlGaN (AlGaN layer) was used as the electron supply layer ES, other group III nitride semiconductor having a band gap larger than that of the channel layer CH may also be used. For example, AlN, GaN, AlGaInN, InGaN, etc. can be used as the electron supply layer.

Further, in the first to the sixth embodiments, while the undoped group III nitride semiconductors were used as the electron supply layer ES, n-type group III nitride semiconductors may also be used. For example, Si (silicon) may be used as the n-type impurity. Further, a stacked film comprising an undoped group III nitride semiconductor and an n-type group III nitride semiconductor, or a stacked film comprising an undoped group III nitride semiconductor, an n-type group III nitride semiconductor, and an undoped group III nitride semiconductor may also be used as the electron supply layer.

Further, in the first to the sixth embodiments, while AlGaN (AlGaN layer) was used as the contact layer CL, other group III nitride semiconductors such as AlN, GaN, AlGaInN, InGaN, InN, etc. may also be used.

Further, in the first to the sixth embodiments, while GaN (GaN layer) was used as the current block layer CB, other group III nitride semiconductors such as AlGaN, AlN, AlGaInN, InGaN, and InN may also be used.

Further, in the third to the sixth embodiments, while Mg was used as the p-type impurity, other impurities such as zinc (Zn) and hydrogen (H) may also be used.

Further, in the first to the sixth embodiments, while the Ti/Al film was used as the material for the source electrode SE and the drain electrode DE, other metal films such as a Ti/Al/Ni/Au film, Ti/Al/Mo/Au film, and Ti/Al/Nb/Au film may also be used, in which Mo represents molybdenum and Nb represents niobium.

Further, in the first to the sixth embodiments, while the Ni/Au film was used as the material for the gate electrode GE, other metal films such as an Ni/Pd/Au film, a Ni/Pt/Au film, a Ti/Au film, and a Ti/Pd/Au film may also be used, in which Pd represents palladium and Pt represents platinum.

Further, in the first to the sixth embodiments, while alumina was used as the gate insulation film GI, other insulators, for example, silicon nitride (Si₃N₄) and silicon oxide (SiO₂) may also be used.

Further, in the first to the sixth embodiments, while HSQ or solder was used as the bonding layer AL, coating type insulation film comprising, for example, SOG (Spin-On-Glass), SOD (Spin-On-dielectrics), and polyimides may also be used. Further, solders comprising, for example, Sn—Pd, Sn—Sb, Bi—Sn, Sn—Cu, and Sn—In, and conductives adhesives such as an Ni paste, an Au paste, a Pd paste, and a carbon paste may also be used. Further, conductive oxides such as indium oxide (In₂O₃), tin oxide (SnO₂), and zinc oxide (ZnO) may also be used, in which Pd represents lead, Sb represents antimony, Bi represents bismuth, Cu represents copper, and In represents indium.

Further, while device isolation is not shown in cross sectional views explained for the first to the sixth embodiments, a device isolation is provided optionally between devices (FET). The device isolation can be formed, for example, by implanting ions such as N or B (boron) in the group III nitride semiconductor. Ion implantation increases the resistance of the implanted region to act as device isolation. Further, the device may be isolated by etching the outer periphery of a device-forming region (mesa etching).

Further, in the compositional formulae of specific materials (for example, AlGaN) shown in the preferred embodiments, the compositional ratio for each of the elements may be properly set within a range not departing from the gist of the invention.

As has been described above, the present invention is not restricted to the preferred embodiments but can be modified variously within the range not departing from the gist of the invention.

What is claimed is:

1. A method of manufacturing a semiconductor device including the steps of:
(a) epitaxially growing a second nitride semiconductor layer over a first nitride semiconductor layer in a [0001] direction, thereby forming a stack comprising the first nitride semiconductor layer and the second nitride semiconductor layer, and
(b) disposing the stack such that the [000-1] direction of the stack becomes upward and forming a gate electrode on the side of the first nitride semiconductor layer, in which
the first nitride semiconductor layer has a band gap larger than a band gap of the second nitride semiconductor.

2. The method of manufacturing the semiconductor device according to claim 1,
wherein the step (a) includes the step of:
(a1) forming the first nitride semiconductor layer over a first substrate,
(a2) epitaxially growing the second nitride semiconductor layer over the first nitride semiconductor layer in the [0001] direction, thereby forming the stack comprising the first nitride semiconductor layer and the second nitride semiconductor layer,
(a3) bonding a second substrate over the second nitride semiconductor layer, and
(a4) peeling the first substrate from the first nitride semiconductor layer, and
wherein the step (b) is a step of
disposing the stack such that the second substrate is situated below and forming the gate electrode on the side of the first nitride semiconductor layer.

3. The method of manufacturing the semiconductor device according to claim 2, wherein
the first nitride semiconductor layer has a first layer and a second layer, and
the step (a1) is a step of forming a first n-type layer over the first substrate and then forming the second layer over the first layer, and
the step (b) is a step of forming a trench passing through the first layer and then forming the gate electrode over the second layer exposed at the bottom in the trench.

4. The method of manufacturing the semiconductor device according to claim 3, wherein
the step (b) is a step of forming the gate electrode by way of a gate insulation film over the second layer.

5. The method of manufacturing the semiconductor device according to claim 2, wherein
the step (a3) is a step of bonding the second substrate by way of a bonding layer over the second nitride semiconductor layer.

6. The method of manufacturing the semiconductor device according to claim 3, wherein
the step (a2) has a step of further forming a third nitride semiconductor layer having an opening over the second nitride semiconductor layer.

7. The method of manufacturing the semiconductor device according to claim 2, wherein
the step (b) is a step of forming an n-type semiconductor layer by ion implantation in a region excluding a first region over the first nitride semiconductor layer and then forming the gate electrode over the first region.

8. The method of manufacturing the semiconductor device according to claim 7, wherein
the step (b) is a step of forming the gate electrode by way of a gate insulation film over the first region.

9. The method of manufacturing the semiconductor device according to claim 7, wherein
the step (a2) has a step of further forming a third nitride semiconductor layer having an opening over the second nitride semiconductor layer.

10. A semiconductor device including:
a first nitride semiconductor layer formed over a substrate,
a second nitride semiconductor layer formed over the first nitride semiconductor layer and having a band gap larger than a band gap of the first nitride semiconductor layer,
a gate electrode disposed over the second nitride semiconductor layer,
a first electrode disposed on at least one side of the gate electrode in a portion over the second nitride semiconductor layer, and
a first semiconductor region containing impurities formed in one of the second nitride semiconductor layer and the first nitride semiconductor layer on both sides of the gate electrode, in which
a crystal axis direction from the first nitride semiconductor layer to the second nitride semiconductor layer in a stacked portion of the first nitride semiconductor layer and the second nitride semiconductor layer is a [000-1] direction.

11. The semiconductor device according to claim 10, wherein
the first semiconductor region is an n-type region.

12. The semiconductor device according to claim 10, wherein
a bonding layer is provided between the substrate and the first nitride semiconductor layer.

13. The semiconductor device according to claim 11, wherein
the first nitride semiconductor layer, the second nitride semiconductor layer, and the first semiconductor region are stacked orderly from below over the substrate,
the gate electrode is disposed by way of a gate insulation film over the second nitride semiconductor layer,
the first electrode is disposed by way of the first semiconductor region to one side of the gate electrodes in a portion over the second nitride semiconductor layer, and
a second electrode is disposed by way of the first semiconductor region on the other side of the gate electrode in a portion over the second nitride semiconductor layer.

14. The semiconductor device according to claim 13, wherein
the device has a trench passing through the first semiconductor region and reaching as far as the second nitride semiconductor layer, and
the gate electrode is disposed by way of the gate insulation film inside the trench.

15. The semiconductor device according to claim 10, wherein
the first nitride semiconductor layer, the second nitride semiconductor layer, and the first semiconductor region are stacked orderly from below over the substrate and
a second electrode connected electrically with the first nitride semiconductor layer is provided below the first nitride semiconductor layer.

16. The semiconductor device according to claim 15, wherein
the device has a trench passing through the first semiconductor region and reaching as far as the second nitride semiconductor layer, and
the gate electrode is disposed by way of a gate insulation film inside the trench.

17. The semiconductor device according to claim 15, wherein
a second semiconductor region having an opening is provided in a layer below the first nitride semiconductor layer.

18. The semiconductor device according to claim 17, wherein
the second semiconductor region is a p-type region.
